(19) United States
(12) Patent Application Publication
(10) Pub. No.: US 2026/0190320 A1
(43) Pub. Date: Jul. 2, 2026

(54) SEMICONDUCTOR STRUCTURES AND MEMORY ARRAYS

(71) Applicant: Peiching LING, Taipei (TW)

(72) Inventors: Peiching LING, San Jose, CA (US); Nanray WU, Miaoli (TW)

(21) Appl. No.: 18/838,247

(22) PCT Filed: May 5, 2023
(86) PCT No.: PCT/US2023/021090

§ 371 Date: Aug. 14, 2024

(51) Int. Cl. H10B 12/00; G11C 11/404

(52) U.S. Cl. CPC H10B 12/20; G11C 11/404; G11C 2211/4016

(57) ABSTRACT

The present disclosure relates to semiconductor structures, memory arrays, and manufacturing methods thereof. The semiconductor structure includes a first dielectric layer, a semiconductor layer, and a dual gate structure. The semiconductor layer is disposed over the first dielectric layer. The semiconductor layer includes a source region, a drain region, and a body region between the source region and the drain region. The dual gate structure is disposed over the body region. The dual gate structure includes a first gate, a second gate, and a spacing material. The second gate includes a first horizontal section laterally distanced from the first gate. The spacing material is disposed between the first gate and the first horizontal section of the second gate.

### BACKGROUND OF THE INVENTION

### Field of the Invention

The technical field generally relates to semiconductor structures, memory arrays, and manufacturing methods thereof; more particularly, to semiconductor structures for capacitorless memory cells and memory arrays and manufacturing methods thereof.

### Description of Related Art

Dynamic random access memory (DRAM) is utilized in many electronic devices. These include computers, mobile devices, tablets, and consumer electronics, to name a few. DRAM is based on a one-transistor, one-capacitor (1T1C) memory cell architecture. The data is stored as a charge in the capacitor, which is designated as either “0” or “1”, and the transistor controls the access to the data. A continuous goal is increasing of the circuit density, thus increasing the amount of memory in a physical package. However, it becomes more difficult to scale or shrink the DRAM cell at each node, for example, it's difficult to etch the capacitors at high aspect ratios. Also, the manufacturing process of the DRAM cell is incompatible with that of the CPU process, which makes it hard to be embedded into logic circuits.

A concept of a DRAM memory cell based on a transistor alone was introduced. The advantage of this concept is that the memory cell does not require a capacitor. However, the capacitor-less RAM cell may have a very high drain bias that is required to operate the cell, which presents reliability problems and also affects the read/write voltage margin.

It is therefore desirable to have improved structures for memory devices and manufacturing methods and implementation methods thereof.

### SUMMARY

According to the present invention, a semiconductor structure is provided. The semiconductor structure includes a first dielectric layer, a semiconductor layer, and a dual gate structure. The semiconductor layer is disposed over the first dielectric layer. The semiconductor layer includes a source region, a drain region, and a body region between the source region and the drain region. The dual gate structure is disposed over the body region. The dual gate structure includes a first gate, a second gate, and a spacing material. The second gate includes a first horizontal section laterally distanced from the first gate. The spacing material is disposed between the first gate and the first horizontal section of the second gate.

In one embodiment, the semiconductor structure further includes a first gate contact and a second gate contact. The first gate contact is electrically connected to the first gate, and the second gate contact is electrically connected to the second gate.

In one embodiment, both the source region and the drain region are in contact with the first dielectric layer.

In one embodiment, a thickness of the semiconductor layer is in a range between 3 nm and 200 nm.

In one embodiment, a lateral interval between the first horizontal section of the second gate and the first gate is in a range between 0.1 nm and 20 nm.

In one embodiment, a first distance between a bottom surface of the first gate and a top surface of the semiconductor layer is smaller than a second distance between a bottom surface of the first horizontal section of the second gate and the top surface of the semiconductor layer.

In one embodiment, the second gate further includes a second horizontal section and a connection section connecting the first horizontal section and the second horizontal section. The second horizontal section of the second gate is disposed above and overlapped with the first gate.

In one embodiment, a second distance between a bottom surface of the first horizontal section of the second gate and a top surface of the semiconductor layer is smaller than a third distance between a bottom surface of the second horizontal section of the second gate and the top surface of the semiconductor layer.

In one embodiment, the source region is adjacent to the first gate, and the drain region is adjacent to the first horizontal section of the second gate.

In one embodiment, the first gate overlaps a first portion of the body region from a top view, and the first horizontal section of the second gate overlaps a second portion of the body region from a top view.

In one embodiment, the first gate is between the source region and the first horizontal section of the second gate.

In one embodiment, a first length of the first gate is greater than a second length of the first horizontal section of the second gate.

In one embodiment, the semiconductor structure further includes a charge storage layer between the semiconductor layer and the first dielectric layer. The charge storage layer is in contact with the semiconductor layer.

In one embodiment, the charge storage layer is either a polysilicon layer, a silicon nitride layer, or a silicon oxynitride layer.

In one embodiment, both the source region and the drain region are in contact with the charge storage layer.

In one embodiment, the semiconductor structure further includes a back gate. The first dielectric layer is between the back gate and the semiconductor layer.

In one embodiment, the dual gate structure surrounds the body region with two or more sides.

In one embodiment, the first contact is disposed on a bottom side of the first gate.

According to the present invention, a memory array is provided. The memory array includes a first dielectric layer, a semiconductor layer, and a first column of memory cell. The semiconductor layer is disposed over the first dielectric layer. The first column of memory cell includes a first memory cell and a second memory cell arranged in a first direction. Each of the first memory cell and the second memory cell includes a source region in the semiconductor layer, a drain region in the semiconductor layer, a body region in the semiconductor layer between the source region and the drain region, and a first gate and a second gate over the body region. The second gate of the first memory cell includes a first horizontal section laterally distanced from the first gate of the first memory cell. The second gate of the second memory cell includes a first horizontal section laterally distanced from the first gate of the second memory cell. The first gate of the first memory cell is electrically connected to the first gate of the second memory cell, and the second gate of the first memory cell is electrically connected to the second gate of the second memory cell.

In one embodiment, the second gate of the first memory cell further includes a second horizontal section and a connection section connecting the first horizontal section of the first memory cell and the second horizontal section of the first memory cell. The second horizontal section of the second gate of the first memory cell is disposed above and overlapped with the first gate of the first memory cell.

In one embodiment, the body region of the first memory cell is partially depleted when the first memory cell is selected for writing.

In one embodiment, both the body region of the first memory cell and the body region of the second memory cell are floating.

In one embodiment, a first threshold voltage of the first gate of the first memory cell is smaller than a second threshold voltage of the second gate of the first memory cell.

In one embodiment, the first gate of the first memory cell is electrically connected to a first word line of the first column, the second gate of the first memory cell is electrically connected to a second word line of the first column, and the drain region of the first memory cell is electrically connected to a first bit line.

In one embodiment, the first gate of the second memory cell is electrically connected to a first word line of the first column, the second gate of the second memory cell is electrically connected to a second word line of the first column, and the drain region of the second memory cell is electrically connected to a second bit line.

In one embodiment, when the first memory cell is not selected, zero voltage is applied to the first gate, zero voltage is applied to the second gate, and zero voltage is applied to the drain region.

In one embodiment, when the first memory cell is selected for writing, a first voltage is applied to the first gate of the first memory cell, a second voltage is applied to the second gate of the first memory cell, and a third voltage is applied to the drain region of the first memory cell. Each of the first voltage, the second voltage, and the third voltage is positive.

In one embodiment, when the first memory cell is selected for writing, a first channel and a second channel are formed in the body region of the first memory cell. The first channel is overlapped with the first gate of the first memory cell. The second channel is overlapped with the first horizontal section of the second gate of the first memory cell. The first channel is discontinuous with the second channel.

In one embodiment, when the first memory cell is selected for erasing, a first voltage is applied to the first gate of the first memory cell, a second voltage is applied to the second gate of the first memory cell, and zero voltage is applied to the drain region of the first memory cell. Both the first voltage and the second voltage are positive.

In one embodiment, when the first memory cell is selected for reading, zero voltage is applied to the first gate of the first memory cell, a fourth voltage is applied to the second gate of the first memory cell, and a fifth voltage is applied to the drain region of the first memory cell. Both the fourth voltage and the fifth voltage are positive.

In one embodiment, each of the first memory cell and the second memory cell further includes a back gate. The back gate of the first memory cell is overlapped with the body region of the first memory cell. The back gate of the second memory cell is overlapped with the body region of the second memory cell. The first dielectric layer is disposed between the body region of the first memory cell and the back gate of the first memory cell. The first dielectric layer is disposed between the body region of the second memory cell and the back gate of the second memory cell.

In one embodiment, the back gate of the first memory cell is electrically connected to the back gate of the second memory cell.

In one embodiment, the back gate of the first memory cell is electrically connected to a third word line of the first column.

In one embodiment, when the first memory cell is not selected, a sixth voltage is applied to the back gate of the first memory cell. The sixth voltage is negative.

In one embodiment, when the first memory cell is selected for writing, a sixth voltage is applied to the back gate of the first memory cell. The sixth voltage is negative.

In one embodiment, when the first memory cell is selected for erasing, zero voltage is applied to the back gate of the first memory cell.

In one embodiment, when the first memory cell is selected for reading, zero voltage is applied to the back gate of the first memory cell.

In one embodiment, a lateral interval between the first horizontal section of the second gate of the first memory cell and the first gate of the first memory cell is in a range between 0.1 nm and 20 nm.

In one embodiment, the memory array further Includes a second column of memory cell. The second column of memory cell includes a third memory cell including a source region in the semiconductor layer, a drain region in the semiconductor layer, a body region in the semiconductor layer between the source region and the drain region, and a first gate and a second gate over the body region. The second gate of the third memory cell includes a first horizontal section laterally distanced from the first gate of the third memory cell. The first memory cell and the third memory cell are arranged in a second direction different from the first direction.

In one embodiment, the first gate of the third memory cell is electrically connected to a first word line of the second column, the second gate of the third memory cell is electrically connected to a second word line of the second column, and the drain region of the third memory cell is electrically connected to a first bit line.

In one embodiment, the source region of the first memory cell and the source region of the third memory cell share a source contact.

In one embodiment, the drain region of the first memory cell and the drain region the first memory cell share a drain contact.

In one embodiment, the first memory cell and the third memory cell are spaced by isolation material.

In one embodiment, each of the first memory cell and the third memory cell further includes a back gate. The back gate of the first memory cell is overlapped with the body region of the first memory cell. The back gate of the third memory cell is overlapped with the body region of the third memory cell. The first dielectric layer is disposed between the body region of the first memory cell and the back gate of the first memory cell. The first dielectric layer is disposed between the body region of the third memory cell and the back gate of the third memory cell.

In one embodiment, the back gate of the first memory cell is electrically connected to the back gate of the third memory cell.

According to the present invention, a method for making a semiconductor structure is provided. The method for making a semiconductor structure includes: receiving a first structure including a first substrate over a first dielectric layer (step (a)); defining an active area in the first substrate (step (b)); forming a dual gate structure over the active area (step (c)); and forming a source region and a drain region in the active area (step (d)). The dual gate structure includes a first gate, a second gate including a first horizontal section laterally distanced from the first gate, and a spacing material laterally between the first gate and the first horizontal section of the second gate.

In one embodiment, the first substrate is a single crystalline substrate made of silicon, germanium, gallium arsenide (GaAs), indium phosphide (InP), silicon carbon (SiC), or gallium nitride (GaN).

In one embodiment, the step (c) includes: forming the first gate over the first gate dielectric (step (c1)); forming the spacing material on a sidewall of the first gate (step (c2)); forming the second gate adjacent to the spacing material such that the first gate and the second gate are spaced apart by the spacing material (step (c3)).

In one embodiment, the step (c2) includes forming at least one of a first gate spacer and a second gate dielectric on the sidewall of the first gate.

In one embodiment, a body region in the active area is doped with a first type of material before step (c).

In one embodiment, in the step (d), the source region and the drain region are formed by doping regions of the active area with a second type of material different from the first type of material.

In one embodiment, the step (d) includes forming the source region and the drain region extending through the thickness of the first substrate.

In one embodiment, the method further includes forming a source contact on the source region and a drain contact on the drain region (step (e)).

In one embodiment, in the step (a) the first structure further includes a second substrate, and the first dielectric layer is disposed between the first substrate and the second substrate.

In one embodiment, the method further includes: removing the second substrate (step (f)); and forming a back gate on the first substrate (step (g)). The first substrate is between the dual gate structure and the back gate.

In one embodiment, in the step (a) the first structure further includes a charge storage layer between the first substrate and the first dielectric layer.

In one embodiment, in the step (a) the first structure further includes a conductive layer, and the first dielectric layer is disposed between the first substrate and the conductive layer.

In one embodiment, in the step (a) the first structure further includes a second dielectric layer, wherein the conductive layer is disposed between the first dielectric layer and the second dielectric layer.

According to the present invention, a method for operating a memory cell is provided. The method for operating a memory cell includes charging a body region of the memory cell by generating electron-hole pairs in the body region of the memory cell between a first channel and a second channel and storing the holes of the electron-hole pairs in the body region; and discharging the body region of the memory cell by reducing the holes stored in the body region. The body region of the memory cell is floating. The first channel is discontinuous with the second channel.

In one embodiment, forming the first channel includes applying a first voltage to a first gate over a first portion of the body region, and forming the second channel includes applying a second voltage to a second gate over a second portion of the body region.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a schematic cross-sectional view to illustrate a semiconductor structure according to an embodiment of the present disclosure.

FIG. 1B is a detailed view of a portion of the semiconductor structure as shown in FIG. 1A according to an embodiment of the present disclosure.

FIG. 1C is a schematic top view to illustrate a memory array including the semiconductor structure as shown in FIG. 1A according to an embodiment of the present disclosure.

FIG. 1D is an electronic schematic diagram to illustrate the memory array as shown in FIG. 1C according to an embodiment of the present disclosure.

FIG. 2 is a schematic view to illustrate a semiconductor structure under an operational state according to an embodiment of the present disclosure.

FIGS. 3 and 4 are schematic cross-sectional views to illustrate semiconductor structures according to embodiments of the present disclosure.

FIG. 5A is a schematic cross-sectional view to illustrate a semiconductor structure according to an embodiment of the present disclosure.

FIG. 5B is a schematic top view to illustrate a memory array including the semiconductor structure as shown in FIG. 5A according to an embodiment of the present disclosure.

FIG. 5C is an electronic schematic diagram to illustrate the memory array as shown in FIG. 5B according to an embodiment of the present disclosure.

FIG. 6A is a schematic cross-sectional view to illustrate a semiconductor structure according to an embodiment of the present disclosure.

FIG. 6B is a schematic top view to illustrate a memory array including the semiconductor structure as shown in FIG. 6A according to an embodiment of the present disclosure.

FIG. 6C is an electronic schematic diagram to illustrate the memory array as shown in FIG. 6B according to an embodiment of the present disclosure.

FIG. 7 is a schematic cross-sectional view to illustrate a semiconductor structure according to an embodiment of the present disclosure.

FIGS. 8A to 8D are schematic views to illustrate a semiconductor structure according to an embodiment of the present disclosure.

FIGS. 9 to 11 are schematic views to illustrate portions of memory arrays according to some embodiments of the present disclosure.

FIGS. 12A to 12K are schematic views to illustrate intermediate stages in the manufacture of a semiconductor structure according to an embodiment of the present disclosure.

FIG. 13 is a schematic cross-sectional view to illustrate an intermediate stage in the manufacture of a semiconductor structure according to an embodiment of the present disclosure.

FIGS. 14A to 14E are schematic views to illustrate intermediate stages in the manufacture of a semiconductor structure according to an embodiment of the present disclosure.

FIG. 15 is a table of voltages provided to a memory cell similar to the memory cell as shown in FIGS. 1A to 1D under various operation modes according to an embodiment of the present disclosure.

FIG. 16 is a table of exemplified voltages provided to a memory cell similar to the memory cells as shown in FIGS. 1A to 1D under various operation modes according to an embodiment of the present disclosure.

FIG. 17 is a table of voltages provided to a memory cell similar to the memory cells as shown in FIGS. 5A to 5C under various operation modes according to an embodiment of the present disclosure.

FIG. 18 is a table of exemplified voltages provided to a memory cell similar to the memory cells as shown in FIGS. 5A to 5C under various operation modes according to an embodiment of the present disclosure.

### DETAILED DESCRIPTION OF PREFERRED EMBODIMENTS

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section.

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

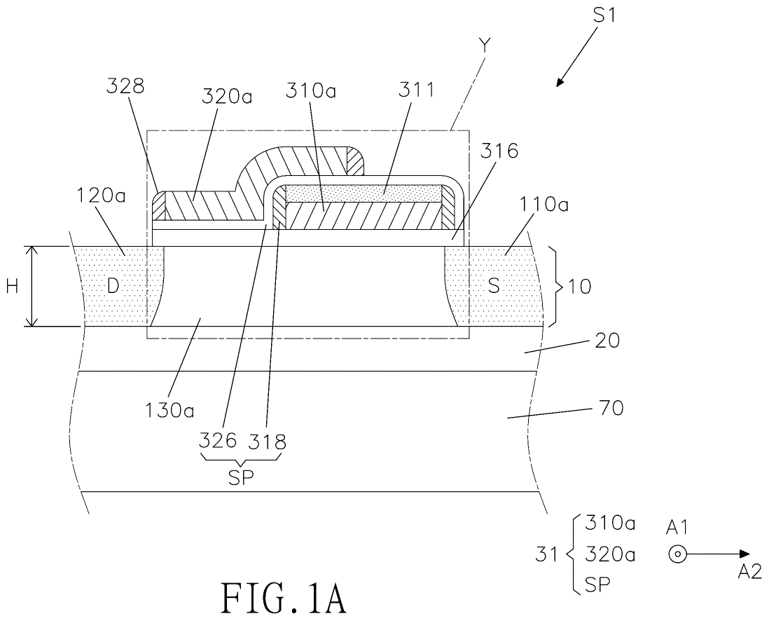

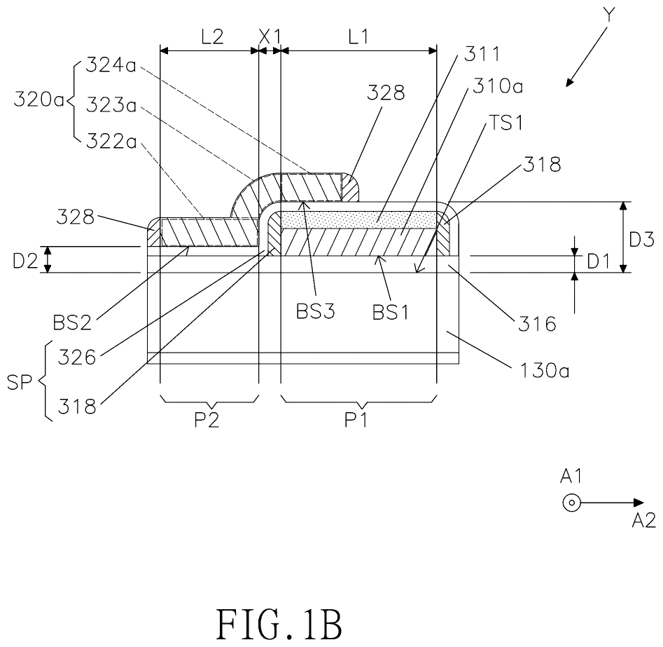

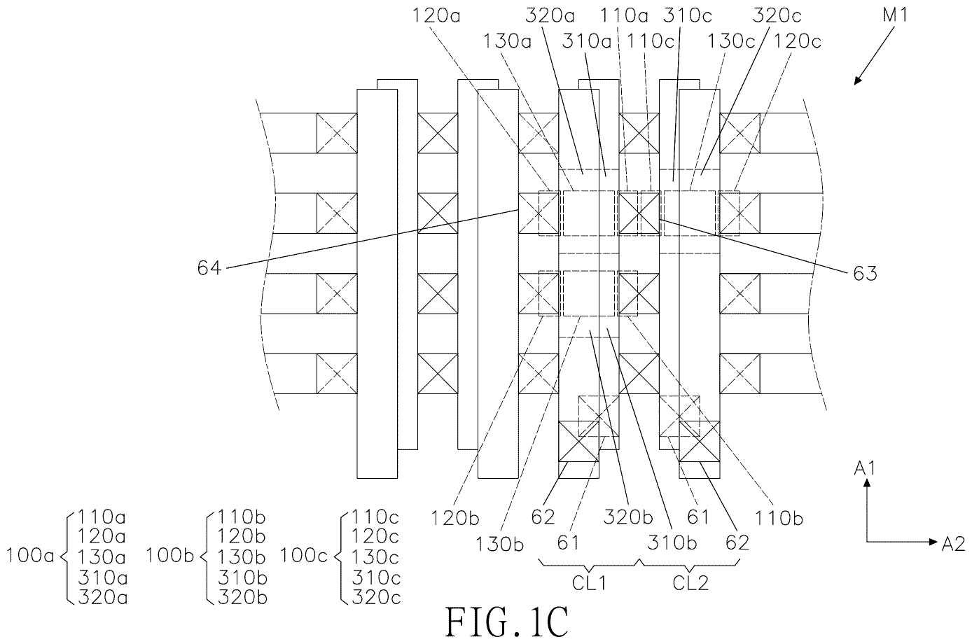

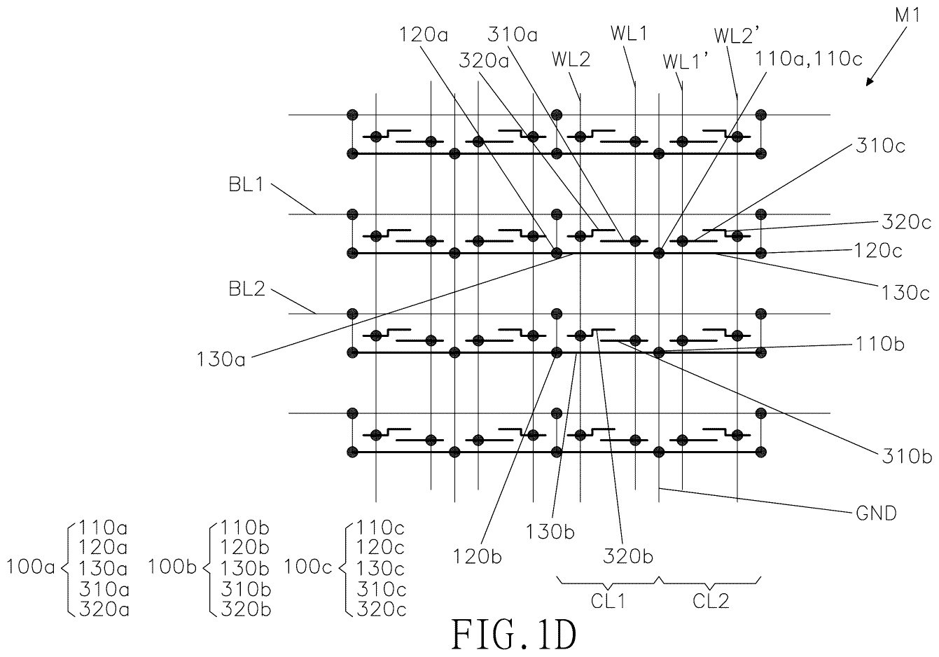

FIG. 1A is a schematic cross-sectional view to illustrate a semiconductor structure, and FIG. 1B is a detailed view of a portion of the semiconductor structure as shown in FIG. 1A, according to an embodiment of the present disclosure. Specifically, FIG. 1B is a detailed view of the portion Y of the semiconductor structure S1 as shown in FIG. 1A. Referring to FIGS. 1A and 1B, the semiconductor structure S1 comprises a semiconductor layer 10, a first dielectric layer 20, and a dual gate structure 31. The semiconductor layer 10 is disposed over the first dielectric layer 20. The semiconductor layer 10 may comprise a single crystalline semiconductor material. The semiconductor material may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. The first dielectric layer 20 may comprise silicon dioxide, although other dielectric materials are also possible.

As shown in FIG. 1A, the semiconductor structure S1 may further comprise a support substrate 70, and the first dielectric layer 20 may be disposed between the semiconductor layer 10 and the support substrate 70. In some embodiments, the support substrate 70 may comprise semiconductor materials described above. In some embodiments, the semiconductor structure S1 may be formed from a silicon-on-insulator (SOI) substrate, a silicon-metal-on-insulator (SMOI) substrate, a silicon-etch-stopper-on-insulator (SEOI), or a silicon-metal-etch-stopper-on-insulator (SMEOI) substrate, and the first dielectric layer 20 may be the “insulator layer” or the “buried oxide (BOX) layer” thereof.

The semiconductor layer 10 comprises a first source region 110a, a first drain region 120a, and a first body region 130a. The first body region 130a may be disposed between the first source region 110a and the first drain region 120a. As shown in FIG. 1A, the first source region 110a is adjacent to one side of the first body region 130a such that a junction (not shown) may be formed therebetween, and the first drain region 120a is adjacent to an opposite side of the first body region 130a such that a junction (not shown) may be formed therebetween. The first body region 130a may be doped with a first type of dopant, and the first source region 110a and the first drain region 120a may be doped with a second type of dopant, which is the opposite of the first conductivity type of dopant. In some embodiments, the first type of dopant may be p-type dopant, such as boron (B), boron fluoride (BF2), gallium (Ga), indium (In), and thallium (Tl), and the second type of dopant may be n-type dopant, such as phosphorus (P), arsenic (As) and antimony (Sb). In other embodiments, the first type of dopant may be n-type dopant as described above, and the second type of dopant may be p-type dopant as described above.

In some embodiments, the doping concentration of the first body region 130a may be from about 1.0×10¹⁵ atoms/cm³ to about 1.0×10¹⁹ atoms/cm³. In some embodiments, the doping concentration of the first source region 110a and the first drain region 120a may be from about 3.0×10¹⁹ atoms/cm³ to about 3.0×10²¹ atoms/cm³. These values are merely examples and are not intended to be limiting. In the embodiment shown in FIGS. 1A and 1B, the semiconductor layer 10 is in direct contact with the first dielectric layer 20, and the first source region 110a and the first drain region 120a may extend through the thickness of the semiconductor layer 10 to the first dielectric layer 20. In other words, both the first source region 110a and the first drain region 120a may be in contact with the first dielectric layer 20.

As shown in FIGS. 1A and 1B, the dual gate structure 31 is disposed over the first body region 130a. The dual gate structure 31 comprises a first gate 310a, a second gate 320a, and a spacing material SP. The second gate 320a may comprise a first horizontal section 322a. The first horizontal section 322a may be an entire portion of the second gate 320a the bottom surface of which (e.g., the bottom surface BS2) is substantially horizontal (or level) relative to the top surface of the first body region (e.g., the top surface TS1 of the first body region 130a). The dual gate structure 31 is sandwiched in the lateral direction (e.g., the second direction A2) by the first source region 110a and the first drain region 120a, wherein the first source region 110a is adjacent to the first gate 310a without overlapped with first gate 310a, and the first drain region 120a is adjacent to the first horizontal section 322a of the second gate 320a without overlapped with the first horizontal section 322a of the second gate 320a. As shown in FIG. 1A, an edge of the first source region 110a is approximately aligned to an end of the first gate 310a, and an edge of the first drain region 120a is approximately aligned to an end of the first horizontal section 322a of the second gate 320a. Each of the first gate 310a and the second gate 320a may comprise conductive material. The conductive material, by way of example and not limitation, can include doped polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The conductive material can further include dopants that are incorporated during or after deposition. Each of the first gate 310a and the second gate 320a may further comprise a work function setting layer. The work function setting layer can be a nitride, including but not limited to titanium nitride (TiN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN); a carbide, including but not limited to titanium carbide (TiC), titanium aluminum carbide (TiAlC), tantalum carbide (TaC), hafnium carbide (HfC), and combinations thereof.

The semiconductor structure S1 may further comprise a first gate dielectric 316. The first gate dielectric 316 may be disposed between the dual gate structure 31 and the first body region 130a of the semiconductor layer 10. The first gate dielectric 316, by way of example and not limitation, may be formed from silicon oxide, silicon nitride, silicon oxynitride, boron nitride, SiOCN, SiBCN, SiOC, SiCN, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, the first gate dielectric 316 can include a combination of the above materials. The semiconductor structure S1 may further comprise a second gate dielectric 326. The second gate dielectric 326 may be disposed between the first gate 310a and the second gate 320a and/or between the dual gate structure 31 and the first body region 130a of the semiconductor layer 10. The second gate dielectric 326 may be formed from similar materials as described for the first gate dielectric 316. Despite that the first gate dielectric 316 is shown as having a uniform thickness, in some embodiments, a portion of the first gate dielectric 316 under the first horizontal section 322a of the second gate 320a may be thinner than a portion of the first gate dielectric 316 under the first gate 310a. In some embodiments, the first gate dielectric 316 may not exist under the first horizontal section 322a of the second gate 320a, and the first horizontal section 322a of the second gate 320a and the first body region 130a may be spaced by the second gate dielectric 326.

As shown in FIGS. 1A and 1B, the semiconductor structure S1 may further comprise first gate spacers 318. The first gate spacers 318 can be formed on sidewalls of the first gate 310a. In some embodiments, the first gate spacers 318 can include silicon oxide, silicon nitride, silicon oxynitride, silicon carbide, silicon oxycarbide, any suitable dielectric material, and/or combinations thereof. In some embodiments, the first gate spacers 318 can be formed using any suitable low-k dielectric material (e.g., a material having dielectric constant lower than about 3.9). The semiconductor structure S1 may further comprise second gate spacers 328 formed on sidewalls of the second gate 320a. The second gate spacers 328 may be formed from similar materials as described for the first gate spacers 318. In the embodiment shown in FIGS. 1A and 1B, the semiconductor structure S1 may further comprise a dielectric mask 311 on the first gate 310a. The first gate 310a and the second gate 320a may be electrically isolated by the first gate spacer 318, the second gate dielectric 326, and/or the dielectric mask 311.

As shown in FIGS. 1A and 1B, the first horizontal section 322a of the second gate 320a may be laterally distanced from the first gate 310a. In other words, the first horizontal section 322a of the second gate 320a is separated from the first gate 310a by a non-zero lateral interval X1. The lateral interval X1 may be calculated by the interval between the edge of the bottom surface BS2 of the first horizontal section 322a of the second gate 320a and the edge of the bottom surface BS1 of the first gate 310a in the lateral direction (e.g., the second direction A2), as it is marked in FIG. 1B. In some embodiments, the lateral interval X1 between the first horizontal section 322a of the second gate 320a and the first gate 310a is in a range between 0.1 nm and 20 nm. In some embodiments, the lateral interval X1 between the first horizontal section 322a of the second gate 320a and the first gate 310a is in a range between 0.5 nm and 10 nm. In some embodiments, the lateral interval X1 between the first horizontal section 322a of the second gate 320a and the first gate 310a is in a range between 2 nm and 3 nm. However, these values are merely examples and are not intended to be limiting. Spacing material SP may be disposed laterally between the first gate 310a and the first horizontal section 322a of the second gate 320a. The spacing material SP may include dielectric material. In the embodiment shown in FIGS. 1A and 1B, the spacing material SP can include a portion of the first gate spacer 318 and/or a portion of the second gate dielectric 326. In some embodiments, the spacing material SP or a portion of the spacing material SP (e.g., the first gate spacer 318) may be formed at a predetermined width. As such, the lateral interval X1 between the first horizontal section 322a of the second gate 320a and the first gate 310a can be controlled.

The second gate 320a may further comprise a second horizontal section 324a. The second horizontal section 324a may be another section of the second gate 320a the bottom surface of which (e.g., the bottom surface BS3) is substantially horizontal (or level) relative to the top surface of the first body region (e.g., the top surface TS1 of the first body region 130a). As shown in FIGS. 1A and 1B, the second horizontal section 324a may be disposed above the first gate 310a and may be overlapped with the first gate 310a from a top view. The second gate 320a may further comprise a connection section 323a connecting the first horizontal section 322a of the second gate 320a and the second horizontal section 324a of the second gate 320a.

As shown in FIGS. 1A and 1B, the first gate 310a is overlapped with a first portion P1 of the first body region 130a, and the first horizontal section 322a of the second gate 320a is overlapped with a second portion P2 of the first body region 130a. The first gate 310a may be disposed laterally between the first source region 110a and the first horizontal section 322a of the second gate 320a, and the first horizontal section 322a may be disposed laterally between the first gate 310a and the first drain region 120a. In the embodiment shown in FIGS. 1A and 1B, the first drain region 120a, the first horizontal section 322a of the second gate 320a, the first gate 310a, and the first source region 110a may be sequentially arranged in the second direction A2. In the embodiment shown in FIGS. 1A and 1B, the entire region of the first body region 130a may be doped with the same type of dopant (e.g., the first type of dopant as described above) and may not include a sub-region doped with a different type of dopant (e.g., the second type of dopant).

The first gate 310a has a first length L1 along the second direction A2, and the first horizontal section 322a of the second gate 320a has a second length L2 along the second direction A2. In some embodiments, The first length L1 is greater than the second length L2. In some embodiments, the first length L1 can be substantially equal to the critical dimension of the lithographic process performed, and the second length L2 can be less than the critical dimension. As such, the size of the semiconductor structure can be reduced. However, the present disclosure is not limited thereto.

In some embodiments, a thickness H1 of the semiconductor layer 10 is in a range between 3 nm and 200 nm. In some embodiments, the thickness H1 may be in a range between 5 nm and 100 nm. These values are merely examples and are not intended to be limiting. As such, the first body region 130a may be partially depleted during at least some operation of the semiconductor structure S1.

Referring to FIG. 1B, in some embodiments, a first distance D1 between a bottom surface BS1 of the first gate 310a and a top surface TS1 of the semiconductor layer 10 is smaller than a second distance D2 between a bottom surface BS2 of the first horizontal section 322a of the second gate 320a and the top surface TS1 of the semiconductor layer 10. In other words, the first horizontal section 322a of the second gate 320a may be “higher” than the first gate 310a with respect to the semiconductor layer 10. As such, a first threshold voltage of the first gate 310a may be smaller than a second threshold voltage of the second gate 320a. However, the disclosure is not limited thereto. In some other embodiments, the first distance D1 can be substantially equal to or larger than the second distance D2. In some other embodiments, the first threshold voltage of the first gate 310a can be substantially equal to or larger than the second threshold voltage of the second gate 320a.

In the embodiment shown in FIGS. 1A and 1B, the second distance D2 between the bottom surface BS2 of the first horizontal section 322a of the second gate 320a and the top surface TS1 of the semiconductor layer 10 is smaller than a third distance D3 between a bottom surface BS3 of the second horizontal section 324a of the second gate 320a and the top surface TS1 of the semiconductor layer 10. In other words, the second horizontal section 324a of the second gate 320a may be located “higher” than the first horizontal section 322a of the second gate 320a with respect to the semiconductor layer 10. As such, the first horizontal section 322a, the connection section 323a, and the second horizontal section 324a of the second gate 320a may altogether constitute a “step-shaped” structure. Such configuration may reduce the size of the semiconductor structure.

FIG. 1C is a schematic top view to illustrate a memory array including the semiconductor structure as shown in FIG. 1A, and FIG. 1D is an electronic schematic diagram to illustrate the memory array as shown in FIG. 1C, according to an embodiment of the present disclosure. Referring to FIGS. 1A to 1D, the memory array M1 comprises a first dielectric layer 20, a semiconductor layer 10, and a first column of memory cell CL1. The semiconductor layer 10 is disposed over the first dielectric layer 20. The first column of memory cell CL1 comprises a first memory cell 100a and a second memory cell 100b arranged in a first direction A1. The first memory cell 100a comprises a first source region 110a disposed in the semiconductor layer 10, a first drain region 120a disposed in the semiconductor layer 10, and a first body region 130a disposed in the semiconductor layer 10 between the first source region 110a and the first drain region 120a. The second memory cell 100b comprises a second source region 110b disposed in the semiconductor layer 10, a second drain region 120b disposed in the semiconductor layer 10, and a second body region 130b disposed in the semiconductor layer 10 between the second source region 110b and the second drain region 120b.

The first source region 110a, the first drain region 120a, and the first body region 130a are described above with regard to the semiconductor structure S1 in FIGS. 1A and 1B. The second source region 110b and the second drain region 120b may be similar to the first source region 110a and the first drain region 120a and may be doped with the same type of dopant as the first source region 110a and the first drain region 120a (e.g., the second type of dopant). The second body region 130b may be similar to the first body region 130a and may be doped with the same type of dopant as the first body region 130a (e.g., the first type of dopant).

The first memory cell 100a may further comprise a first gate 310a and a second gate 320a over the first body region 130a. The second gate 320a comprises a first horizontal section 322a laterally distanced from the first gate 310a. The first gate 310a and the second gate 320a are described above with regard to the semiconductor structure S1 in FIGS. 1A and 1B. The first memory cell 100a can be controlled by the first gate 310a and the second gate 320a. Similarly, the second memory cell 100b may further comprise a first gate 310b and a second gate 320b over the second body region 130b, and the second gate 320b comprises a first horizontal section 322b laterally distanced from the first gate 310b. The first gate 310b and the second gate 320b of the second memory cell 100b may be similar to the first gate 310a and the second gate 320a of the first memory cell 100a. The second memory cell 100b can be controlled by the first gate 310b and the second gate 320b.

The first gate 310a of the first memory cell 100a may be electrically connected to the first gate 310b of the second memory cell 100b, and the second gate 320a of the first memory cell 100a may be electrically connected to the second gate 320b of the second memory cell 100b. As shown in FIG. 1C, in the memory array M1, the first gate 310a of the first memory cell 100a may extend in the first direction A1 and may be connected with the first gate 310b of the second memory cell 100b to form a “gate line” extending across the first memory cell 100a and the second memory cell 100b. Similarly, the second gate 320a of the first memory cell 100a may extend in the first direction A1 and may be connected with the second gate 320b of the second memory cell 100b to form a “gate line” extending across the first memory cell 100a and the second memory cell 100b.

In the embodiment shown in FIGS. 1C to 1D, the memory array M1 may further comprise a second column of memory cell CL2. The second column of memory cell CL2 comprises a third memory cell 100c. The first memory cell 100a and the third memory cell 100c may be arranged in a second direction A2 different from the first direction A1. The third memory cell 100c may be of a similar structure as the first memory cell 100a. Specifically, the third memory cell 100c may comprise a third source region 110c disposed in the semiconductor layer 10, a third drain region 120c disposed in the semiconductor layer 10, and a third body region 130c disposed in the semiconductor layer 10 between the third source region 110c and the third drain region 120c. The third source region 110c and the third drain region 120c may be similar to the first source region 110a and the first drain region 120a described above with reference to FIGS. 1A and 1B and may be doped with the same type of dopant as the first source region 110a and the first drain region 120a (e.g., the second type of dopant). The third body region 130c may be similar to the first body region 130a described above with reference to FIGS. 1A and 1B and may be doped with the same type of dopant as the first body region 130a (e.g., the first type of dopant).

The third memory cell 100c may further comprise a first gate 310c and a second gate 320c over the third body region 130c, and the second gate 320c comprises a first horizontal section 322c laterally distanced from the first gate 310c. The first gate 310c and the second gate 320c of the third memory cell 100c may be similar to the first gate 310a and the second gate 320a of the first memory cell 100a, respectively. The third memory cell 100c can be controlled by the first gate 310c and the second gate 320c.

Referring to FIGS. 1C and 1D, in the memory array M1, the first gate 310a of the first memory cell 100a and the first gate 310b of the second memory cell 100b are electrically connected to a first word line WL1 of the first column of memory cell CL1, and the second gate 320a of the first memory cell 100a and the second gate and 320b of the second memory cell 100b are electrically connected to a second word line WL2 of the first column of memory cell CL1. The first gate 310c of the third memory cell 100c is electrically connected to a first word line WL1′ of the second column of memory cell CL2, and the second gate 320c of the third memory cell 100c is electrically connected to a second word line WL2′ of the second column of memory cell CL2. The first drain region 120a of the first memory cell 100a and the third drain region 120c of the third memory cell 100c are electrically connected to a first bit line BL1, and the second drain region 120b of the second memory cell 100b is electrically connected to a second bit line BL2. As such, the first memory cell 100a can be operated by signals from the first word line WL1 of the first column of memory cell CL1, the second word line WL2 of the first column of memory cell CL1, and the first bit line BL1; the second memory cell 100b can be operated by signals from the first word line WL1 of the first column of memory cell CL1, the second word line WL2 of the first column of memory cell CL1, and the second bit line BL2; and the third memory cell 100c can be operated by signals from the first word line WL1′ of the second column of memory cell CL2, the second word line WL2′ of the second column of memory cell CL2, and the first bit line BL1.

In the embodiment shown in FIGS. 1C and 1D, the first source region 110a of the first memory cell 100a, the second source region 110b of the second memory cell 100b, and the third source region 110c of the third memory cell 100c may be grounded. The first body region 130a of the first memory cell 100a, the second body region 130b of the second memory cell 100b, and the third body region 130c of the third memory cell 100c may be floating. As such, with appropriate signals from the first word lines, the second word lines, and the bit lines, the first memory cell 100a, the second memory cell 100b, and the third memory cell 100c may be operated as a single transistor capacitor-less (1T0C) memory cell. FIGS. 1C and 1D shows sixteen memory cells from four columns of memory cell, however, the memory array may comprise any number of memory cells arranged in any number of columns.

Referring to FIGS. 1A to 1D, the semiconductor structure S1 may further comprise a first gate contact 61 electrically connected to the first gate 310a. The first gate 310a may be electrically connected to a first word line WL1 through the first gate contact 61, such that the operation voltages can be applied to the first gate 310a through the first word line WL1. The semiconductor structure S1 may further comprise a second gate contact 62 electrically connected to the second gate 320a. The second gate 320a may be electrically connected to a second word line WL2 through the second gate contact 62, such that the operation voltages can be applied to the second gate 320a through the second word line WL2. FIG. 1C shows a first gate contact 61 disposed on the bottom side of the first gate 310a and a second gate contact 62 disposed on the top side of the second gate 320a, however, the number and the position of the gate contacts are merely examples and are not intended to be limiting.

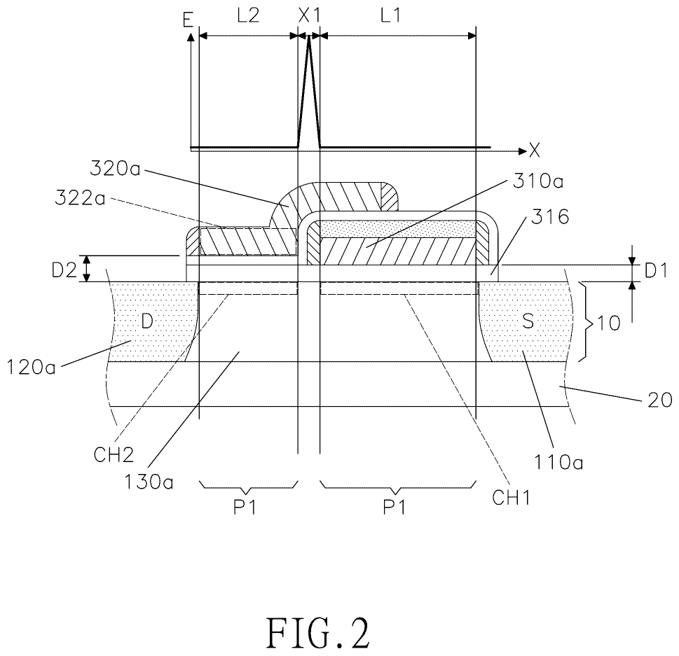

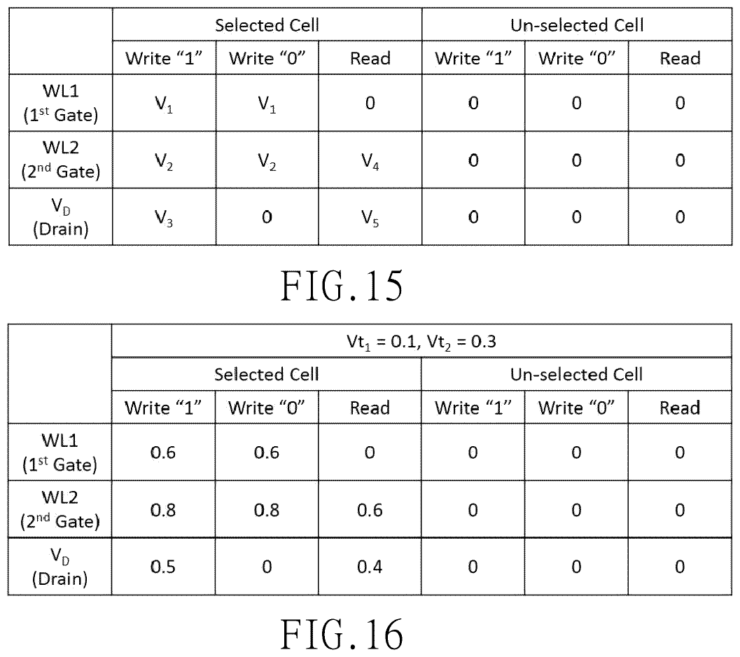

FIG. 2 is a schematic view to illustrate a semiconductor structure under an operational state according to an embodiment of the present disclosure. FIG. 15 is a table of voltages provided to a memory cell similar to the memory cell as shown in FIGS. 1A to 1D (e.g., the first memory cell 100a) under various operation modes, and FIG. 16 is a table of the exemplified voltages provided to a memory cell similar to the memory cells as shown in FIGS. 1A to 1D under various operation modes, according to an embodiment of the present disclosure. In the embodiment shown in FIG. 2, the semiconductor structure may be similar to the semiconductor structure S1 shown in FIGS. 1A to 1B and the description is not repeated herein. In the exemplified embodiment shown in FIG. 2, the first source region 110a and the first drain region 120a are doped with n-type dopant. However, a first source region and a first drain region doped with materials of other conductivity type (e.g., p-type) may also be possible.

Referring to FIG. 2 and FIGS. 15 to 16, when the first memory cell 100a is selected for writing (write “1”), a positive first voltage V1 is applied to the first gate 310a over a first portion P1 of the first body region 130a, and a positive second voltage V2 is applied to the second gate 320a over a second portion P2 of the first body region 130a (the first voltage V1 and the second voltage V2 herein refer to gate-source bias).

The first voltage V1 may be provided with appropriate values (e.g., 0.6 V) such that a first channel CH1 can be formed in the first body region 130a. The first channel CH1 may be an inversion layer induced by the first voltage V1. In some embodiments, the first channel CH1 may extend from a point in the first body region 130a to the first source region 110a and may be overlapped with the first gate 310a. The second voltage V2 may be provided with appropriate values (e.g., 0.8 V) such that a second channel CH2 can be formed in the first body region 130a. The second channel CH2 may be an inversion layer induced by the second voltage V2. As shown in FIG. 2, the first channel CH1 may be discontinuous with the second channel CH2, the second channel CH2 may extend from another point in the first body region 130a distanced from the first channel CH1 to the first drain region 120a and may be overlapped with the first horizontal section 322a of the second gate 320a. The features of the semiconductor structure (e.g., the lateral interval X1 between the first horizontal section 322a of the second gate 320a and the first gate 310a, the first distance D1 between the first gate 310a and the semiconductor layer 10, and/or the second distance D2 between the first horizontal section 322a of the second gate 320a and the semiconductor layer 10) can be set to appropriate values such that a first channel CH1 and a second channel CH2, which is discontinuous with the first channel CH1, can be formed when appropriate voltage is applied to the semiconductor structure. For example, the lateral interval X1 between the first horizontal section 322a of the second gate 320a and the first gate 310a may be set to a value between 0.1 nm and 20 nm, between 0.5 nm and 10 nm, or between 2 nm and 3 nm.

Thereafter, when a positive third voltage V3 (e.g., 0.5 V; the third voltage V3 herein refers to drain-source bias) is applied to the first drain region 120a, electrons may move from the first source region 110a to the first drain region 120a through the first channel CH1 and the second channel CH2. FIG. 2 shows a schematic electric field distribution along the surface portion of the first body region 130a. As shown in FIG. 2, an electric field with relatively small and relatively fixed values is present in the first channel CH1 and the second channel CH2, and an electric field of high values occurs between the first channel CH1 and the second channel CH2 (the “gap region”). The high electric field may accelerate electrons from the first channel CH1 into the second channel CH2, and the acceleration of the electrons may cause them to collide with semiconductor lattice atoms in the gap region, generating electron-hole pairs in the process. The electrons from the electron-hole pairs may be drained out easily, while holes from the electron-hole pairs may be accumulated in the first body region 130a. Specifically, the holes can be stored in the first body region 130a since the first body region 130a is electrically floating. In some embodiments, most of the holes may be stored in a region beneath the first channel CH1 due to the electric field in the first body region 130a. As a result, the first body region 130a can be charged. By charging the first body region 130a, the writing (write “1”) operation of a selected cell can be performed. The first body region 130a of the first memory cell 100a may be partially depleted under the writing operation, such that the charges can be stored in the first body region 130a. The values of the voltages disclosed herein can be adjusted according to the actual situation and are not intended to be limiting.

Referring to FIG. 2 and FIGS. 15 to 16, when the first memory cell 100a is selected for erasing (write “0”), a positive first voltage V1 (e.g., 0.6 V) is applied to the first gate 310a, a positive second voltage V2 (e.g., 0.8 V) is applied to the second gate 320a, and zero voltage (zero drain-source bias) is applied to the first drain region 120a. As such, the electron-hole pairs may no longer be generated (or less electron-hole pairs may be generated) in the first body region 130a due to the drop of the drain-source bias, and at least a portion of the stored holes may be repelled from the first body region 130a to the first source region 110a and/or the first drain region 120a due to the body potential created by the stored holes in the first body region 130a and the voltage applied to the first gate 310a and the second gate 320a. As a result, the holes stored in the first body region 130a may be reduced. By discharging the first body region 130a, the erasing (write “0”) operation of a selected cell can be performed. The values of the voltages disclosed herein can be adjusted according to the actual situation and are not intended to be limiting, moreover, the first voltage V1 and the second voltage V2 applied during the erasing operation can be different from the first voltage V1 and the second voltage V2 applied during the writing operation.

Referring to FIG. 2 and FIGS. 15 to 16, when the first memory cell 100a is selected for reading, zero voltage (zero gate-source bias) is applied to the first gate 310a, and a positive fourth voltage V4 is applied to the second gate 320a (e.g., 0.6V; the fourth voltage V4 herein refers to gate-source bias). If the first memory cell 100a is at “1” state, the first memory cell 100a can be turned “on”, since the threshold voltage of the first gate 310a may be reduced by the stored charges in the first body region 130a. Therefore, when a positive fifth voltage V5 (e.g., 0.4 V; the fifth voltage V5 herein refers to drain-source bias) is applied to the first drain region 120a, a drain current can be detected. If the first memory cell 100a is at “0” state, the first channel may not be formed since fewer charges are stored in the first body region 130a, and the first memory cell 100a would stay “off”. Therefore, when a positive fifth voltage V5 is applied to the first drain region 120a, a drain current may not be detected.

Referring to FIG. 2 and FIGS. 15 to 16, when the first memory cell 100a is not selected, zero voltage (zero gate-source bias) is applied to the first gate 310a, zero voltage (zero gate-source bias) is applied to the second gate 320a, and zero voltage (zero drain-source bias) is applied to the first drain region 120a.

In the present embodiments, the high electric field occurred between the first channel CH1 and the second channel CH2 in the first body region 130a can be more consistent and more controllable, e.g., by determining the value of third voltage V3 applied to the first drain region 120a and/or the lateral interval X1 between the first horizontal section 322a of the second gate 320a and the first gate 310a. As such, the memory cell can work under relatively small drain voltage and relatively small drain current, which makes a large array of the memory cells possible. Also, the read margin of the memory cell can be enhanced. The operation conditions discussed above are examples for operating the memory cell provided herein and are not intended to be limiting.

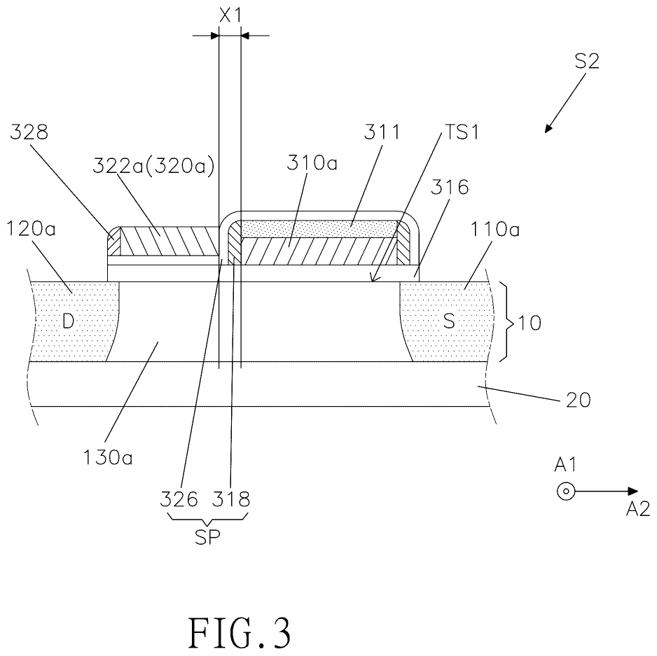

FIG. 3 is a schematic cross-sectional view to illustrate a semiconductor structure according to an embodiment of the present disclosure. Semiconductor structure S2 in FIG. 3 may be substantially similar to semiconductor structure S1 in FIG. 1A where like reference numerals indicate like elements. As shown in FIG. 3, the second gate 320a may include a first horizontal section 322a without including a second horizontal section. In other words, the second gate 320a may be substantially “level” with respect to the top surface TS1 of the first body region 130a. In the embodiment shown in FIG. 3, the second gate 320a may be laterally distanced from the first gate 310a. The lateral interval X1 between the second gate 320a and the first gate 310a may be in a range between 0.1 nm and 20 nm, a range between 0.5 nm and 10 nm, or a range between 2 nm and 3 nm. These values are merely examples and are not intended to be limiting. Spacing material SP, which includes dielectric material including but not limited to the first gate spacer 318 and/or the second gate dielectric 326 shown in FIG. 3 may be disposed between the first gate 310a and the second gate 320a.

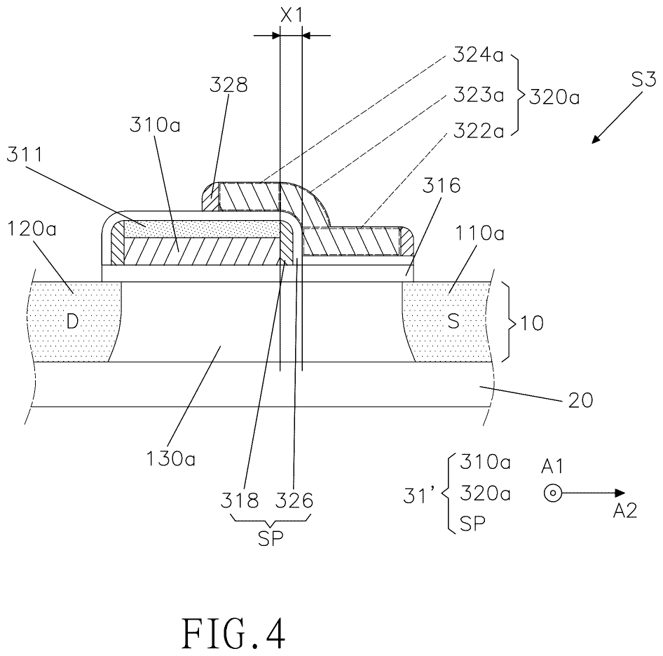

FIG. 4 is a schematic cross-sectional view to illustrate a semiconductor structure according to an embodiment of the present disclosure. Semiconductor structure S3 in FIG. 4 may be substantially similar to semiconductor structure S1 in FIG. 1A where like reference numerals indicate like elements. As shown in FIG. 4, the dual gate structure 31′ comprises a first gate 310a, a second gate 320a, and a spacing material SP. The second gate 320a may comprise a first horizontal section 322a, a second horizontal section 324, and the connection section 323a. The dual gate structure 31′ is sandwiched in the lateral direction (e.g., the second direction A2) by the first source region 110a and the first drain region 120a, wherein the first drain region 120a is adjacent to the first gate 310a without overlapped with first gate 310a, and the first source region 110a is adjacent to the first horizontal section 322a of the second gate 320a without overlapped with the first horizontal section 322a of the second gate 320a. As shown in FIG. 4, an edge of the first drain region 120a is approximately aligned to an end of the first gate 310a, and an edge of the first source region 110a is approximately aligned to an end of the first horizontal section 322a of the second gate 320a. In the embodiment shown in FIG. 4, the first drain region 120a, the first gate 310a, the first horizontal section 322a of the second gate 320a, and the first source region 110a may be sequentially arranged in the second direction A2. A memory cell with such structure may still be operated as a single transistor capacitor-less (1T0C) memory cell if proper operation voltages are applied.

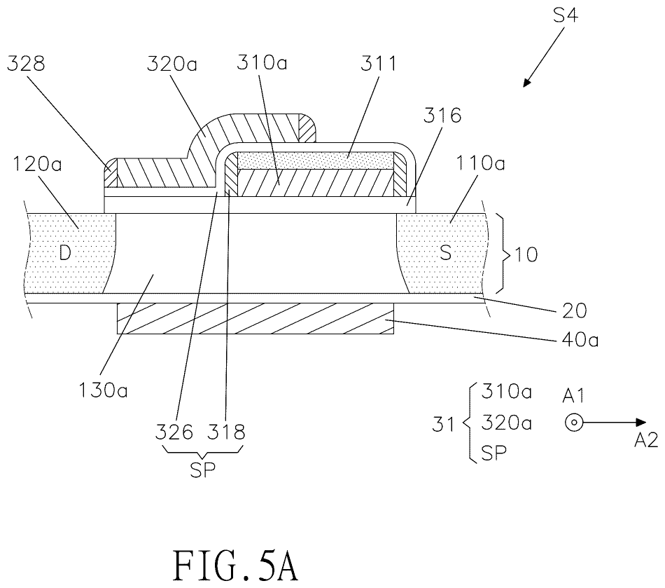

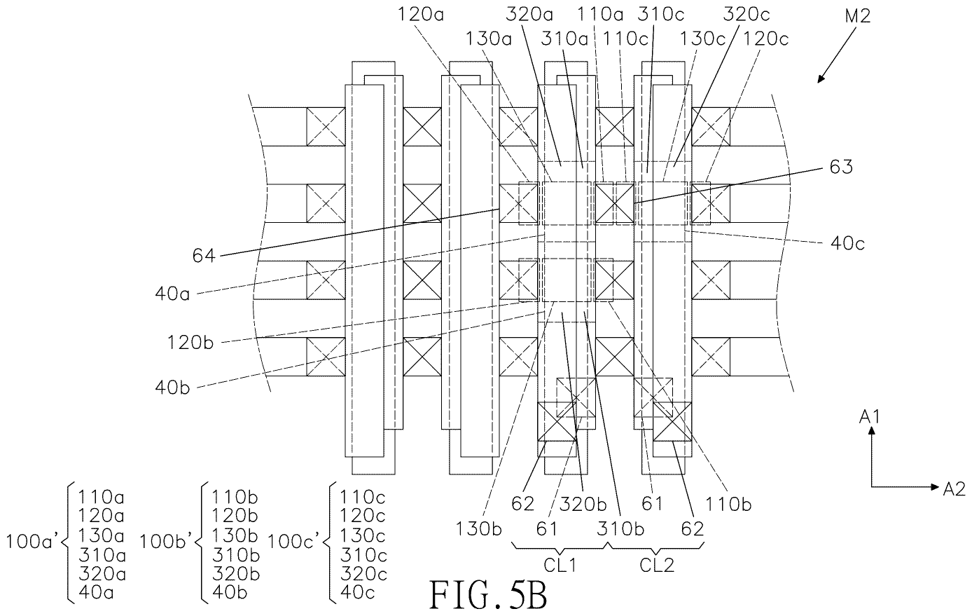

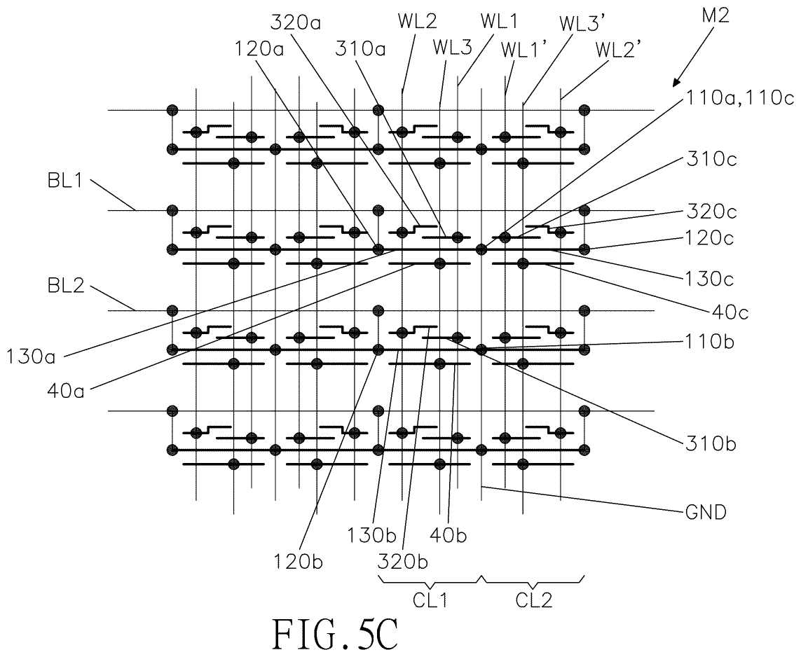

FIG. 5A is a schematic cross-sectional view to illustrate a semiconductor structure according to an embodiment of the present disclosure. FIG. 5B is a schematic top view to illustrate a memory array including the semiconductor structure as shown in FIG. 5A, and FIG. 5C is an electronic schematic diagram to illustrate the memory array as shown in FIG. 5B, according to an embodiment of the present disclosure.

Semiconductor structure S4 in FIG. 5A may be substantially similar to semiconductor structure S1 in FIG. 1A, and memory array M2 in FIGS. 5B and 5C may be substantially similar to memory array M1 in FIGS. 1C and 1D, where like reference numerals indicate like elements. As shown in FIG. 5A, the semiconductor structure S4 may further comprise a back gate 40a, and the first dielectric layer 20 may be disposed between the back gate 40a and the semiconductor layer 10. In some embodiments, the first dielectric layer 20 may be a thin layer of dielectric material which functions as the gate dielectric for the back gate 40a. The back gate 40a may be formed of conductive materials similar to those of the first gate 310a and the second gate 320a described above with reference to FIG. 1A.

Referring to FIGS. 5B and 5C, in the memory array M2, the first memory cell 100a′ may further comprise a back gate 40a overlapped with the first body region 130a from a top view, the second memory cell 100b′ may further comprise a back gate 40b overlapped with the second body region 130b from a top view. The features of the first memory cell 100a′ are shown by semiconductor structure S4 in FIG. 5A, and the second memory cell 100b′ may be of a similar structure as the first memory cell 100a′. Specifically, the first dielectric layer 20 may be disposed between the first body region 130a and the back gate 40a of the first memory cell 100a′, and the first dielectric layer 20 may be disposed between the second body region 130b and the back gate 40b of the second memory cell 100b′. As such, the back gate 40a of the first memory cell 100a′ may function as a charge control gate for the first memory cell 100a′, and the back gate 40b of the second memory cell 100b′ may function as a charge control gate for the second memory cell 100b′. The charge control gate can be used to facilitate charge retention for the memory cell. For example, the charge control gate may be provided with a negative voltage to attract and hold positive charges, such as electric holes, at the bottom of the body region.

Referring to FIGS. 5B and 5C, the back gate 40a of the first memory cell 100a′ may be electrically connected to a third word line WL3 of the first column of memory cell CL1, and the back gate 40b of the second memory cell 100b′ may also be electrically connected to a third word line WL3 of the first column of memory cell CL1. As such, the charge retention for the first memory cell 100a′ and/or the second memory cell 100b′ can be controlled by signals from the third word line WL3 of the first column of memory cell CL1. In the embodiment shown in FIGS. 5B to 5C, the back gate 40a of the first memory cell 100a′ is electrically connected to the back gate 40b of the second memory cell 100b′. In some embodiments, the back gate 40a of the first memory cell 100a′ may extend in the first direction A1 and may be connected with the back gate 40b of the second memory cell 100b′ to form a “gate line” extending across the first memory cell 100a′ and the second memory cell 100b′.

As shown in FIGS. 5B and 5C, in the memory array M2, the third memory cell 100c′ may further comprise a back gate 40c overlapped with the third body region 130c from a top view. The third memory cell 100c′ may be of a similar structure as the first memory cell 100a′. The first dielectric layer 20 may be disposed between the third body region 130c and the back gate 40c of the third memory cell 100c′. As such, the back gate 40c of the third memory cell 100c′ may function as a charge control gate for the third memory cell 100c′.

The back gate 40c of the third memory cell 100c′ may be electrically connected to a third word line WL3′ of the second column of memory cell CL2. As such, the charge retention for the third memory cell 100c′ can be controlled by signals from the third word line WL3′ of the second column of memory cell CL2. In the embodiment shown in FIGS. 5B to 5C, the back gate 40c of the third memory cell 100c′ is not electrically connected to the back gate 40a of the first memory cell 100a′.

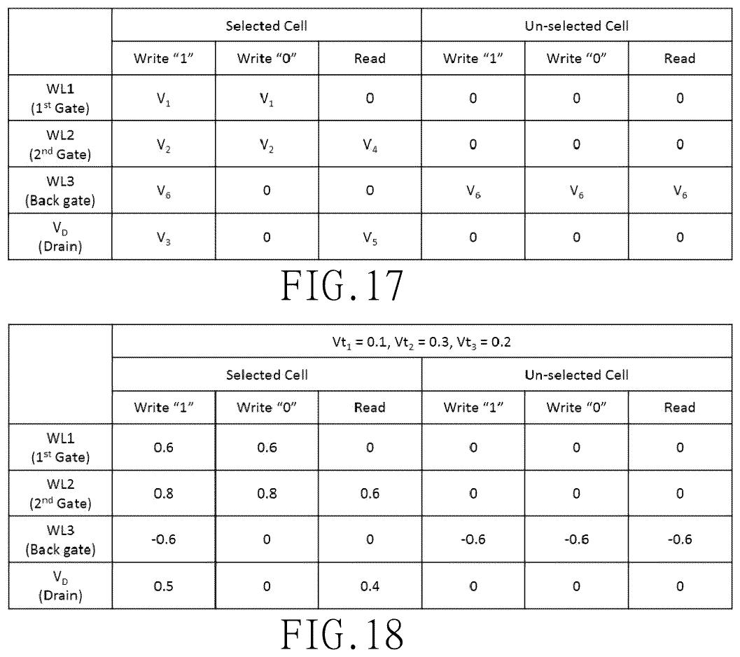

FIG. 17 is a table of voltages provided to a memory cell similar to the memory cells as shown in FIGS. 5A to 5C (e.g., the first memory cell 100a′) under various operation modes, and FIG. 18 is a table of exemplified voltages provided to a memory cell similar to the memory cells as shown in FIGS. 5A to 5C under various operation modes, according to an embodiment of the present disclosure.

Referring to FIGS. 5A to 5C and FIGS. 17 to 18, the voltages applied to the first gate 310a, the second gate 320a, and the first drain region 120a of the first memory cell 100a′ under various operation modes may be similar to those applied to the first memory cell 100a as describe above with regard to FIGS. 15 to 16 and the description is not repeated herein.

Referring to FIGS. 5A to 5C and FIGS. 17 to 18, when the first memory cell 100a′ is selected for writing, a negative sixth voltage V6 (e.g., −0.6 V; the sixth voltage V6 herein refer to gate-source bias) may be applied to the back gate 40a to attract and hold positive charges, such as electric holes, at the bottom of the first body region 130a; and when the first memory cell 100a′ is selected for erasing, zero voltage (zero gate-source bias) may be applied to the back gate 40a. When the first memory cell 100a′ is selected for reading, zero voltage (zero gate-source bias) may be applied to the back gate 40a; and when the first memory cell 100a′ is not selected, a negative sixth voltage V6 (e.g., −0.6 V) may be applied to the back gate 40a to attract and hold positive charges, such as electric holes, at the bottom of the first body region 130a. The operation conditions discussed above are examples for operating the memory cell provided herein and are not intended to be limiting.

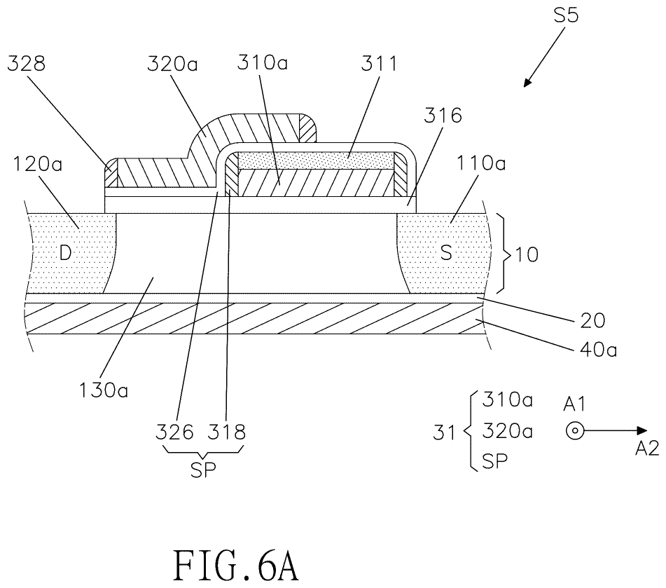

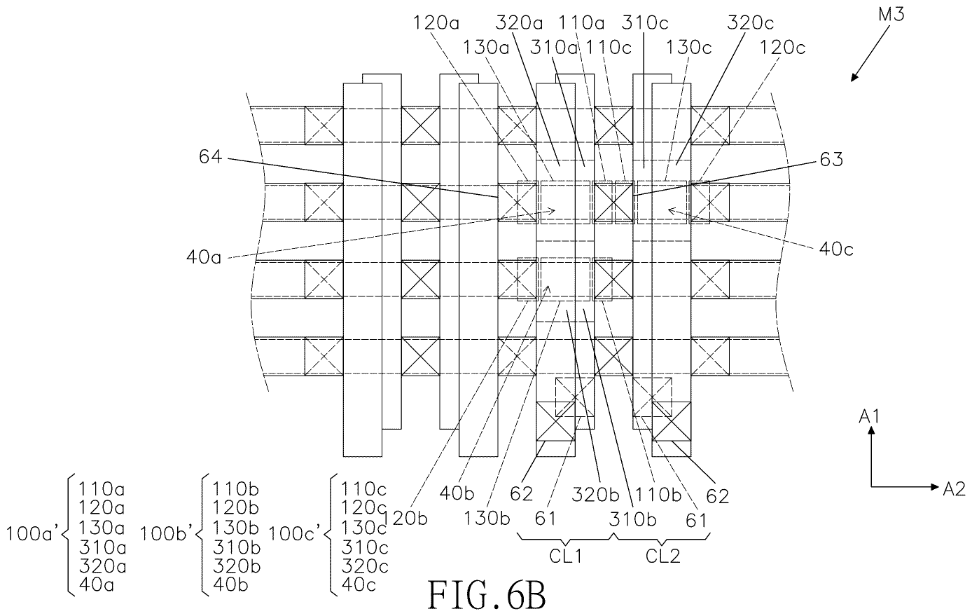

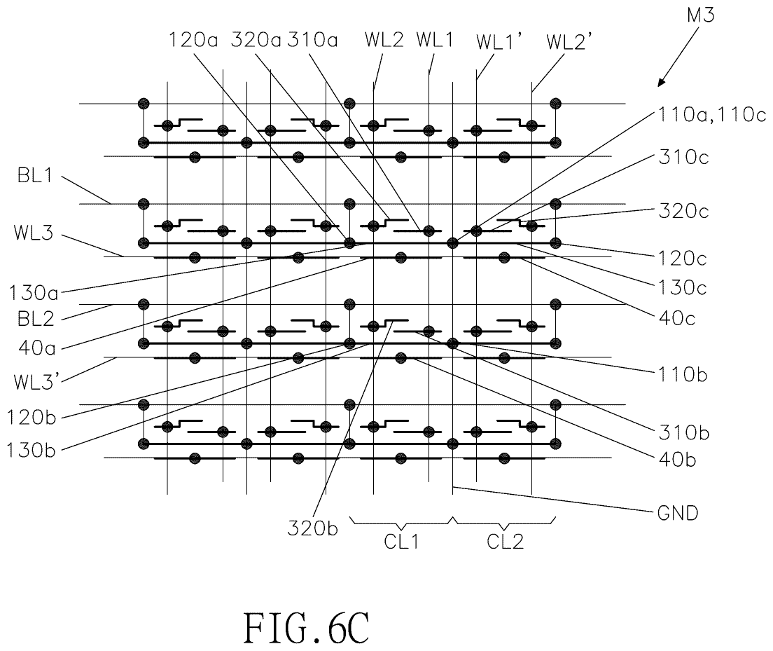

FIG. 6A is a schematic cross-sectional view to illustrate a semiconductor structure according to an embodiment of the present disclosure. FIG. 6B is a schematic top view to illustrate a memory array including the semiconductor structure as shown in FIG. 6A, and FIG. 6C is an electronic schematic diagram to illustrate the memory array as shown in FIG. 6B, according to an embodiment of the present disclosure.

Semiconductor structure S5 in FIG. 6A may be substantially similar to semiconductor structure S4 in FIG. 5A, and memory array M3 in FIGS. 6B and 6C may be substantially similar to memory array M2 in FIGS. 5B and 5C, where like reference numerals indicate like elements. In the embodiment shown in FIGS. 6B to 6C, the back gate 40a of the first memory cell 100a′ may be electrically connected to the back gate 40c of the third memory cell 100c′. In some embodiments, the back gate 40a of the first memory cell 100a′ may extend in the second direction A2 and may be connected with the back gate 40b of the third memory cell 100c′ to form a “gate line” extending across the first memory cell 100a′ and the third memory cell 100c′. As shown in FIGS. 6A to 6C, the back gate 40a of the first memory cell 100a′ may be electrically connected to a third word line WL3 of the first column of memory cell CL1, and back gate 40c of the third memory cell 100c′ may also be electrically connected to the third word line WL3 of the first column of memory cell CL1. As such, the charge retention for the first memory cell 100a′ and/or the third memory cell 100c′ can be controlled by signals from the third word line WL3 of the first column of memory cell CL1. The back gate 40b of the second memory cell 100b′ may be electrically connected to a third word line WL3′ of the second column of memory cell CL2, and the charge retention for the second memory cell 100b′ can be controlled by signals from the third word line WL3′ of the second column of memory cell CL2. In the embodiment shown in FIGS. 6A to 6C, the back gate 40b of the second memory cell 100b′ may not be electrically connected to the back gate 40a of the first memory cell 100a′.

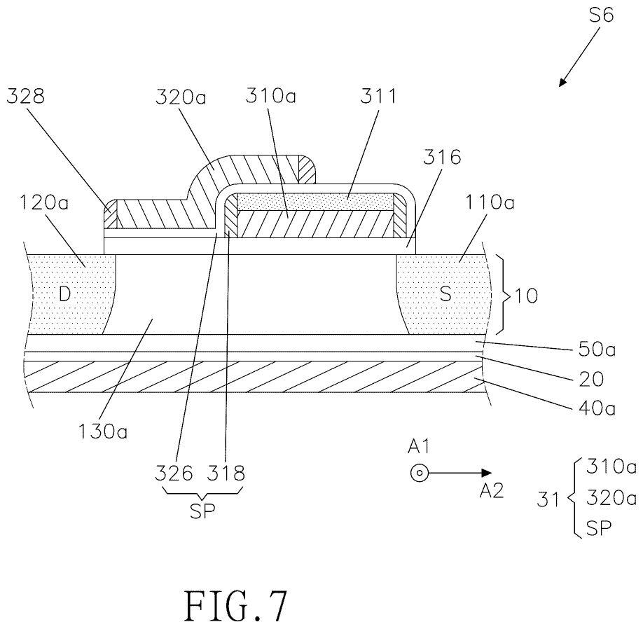

FIG. 7 is a schematic cross-sectional view to illustrate a semiconductor structure according to an embodiment of the present disclosure. Semiconductor structure S6 in FIG. 7 may be substantially similar to semiconductor structure S5 in FIG. 6A, where like reference numerals indicate like elements. As shown in FIG. 7, the semiconductor structure S6 may further comprise a charge storage layer 50 between the semiconductor layer 10 and the first dielectric layer 20. The charge storage layer 50 may be in contact with the semiconductor layer 10 to store charges which can be holes (positive charges) or electrons (negative charges). The first dielectric layer 20 may be disposed between the charge storage layer 50 and the back gate 40a.

The charge storage layer 50 may be a polysilicon layer, a silicon nitride layer, or a silicon oxynitride layer. The thickness of the charge storage layer 50 may be less than 20 nm. In one embodiment, the thickness of the charge storage layer 50 may be less than 5 nm. When the charge storage layer 50 is a polysilicon layer, the holes or electrons may be trapped and stored for a period of time between grain boundaries in the polysilicon layer. Smaller grains generally create more boundaries for trapping either holes or electrons. In general, if the charge storage layer 50 is thinner, the smaller the grains of polysilicon are. Smaller grains generate more surface areas of the boundary to trap electronic holes. During operation of the memory cells, either holes or electrons in the body region may be driven towards the bottom of the semiconductor layer 10 by applying an appropriate voltage to the memory cells (e.g., applying an appropriate voltage to the back gate 40a), and then enter the charge storage layer 50. Such holes or electrons may be trapped and stored for a period of time in the charge storage layer 50. As such, the charge storage layer 50 may facilitate the storage of charge in the memory cell.

In the embodiment shown in FIG. 7, both the first source region 110a and the first drain region 120a are in contact with the charge storage layer 50. As such, the charge (e.g., holes) generated in the first body region 130a may be stored in the first body region 130a and/or in the charge storage layer 50. FIG. 7 shows a semiconductor structure S6 including a charge storage layer 50 and a back gate 40a. However, in other embodiments, the back gate 40a may not be provided.

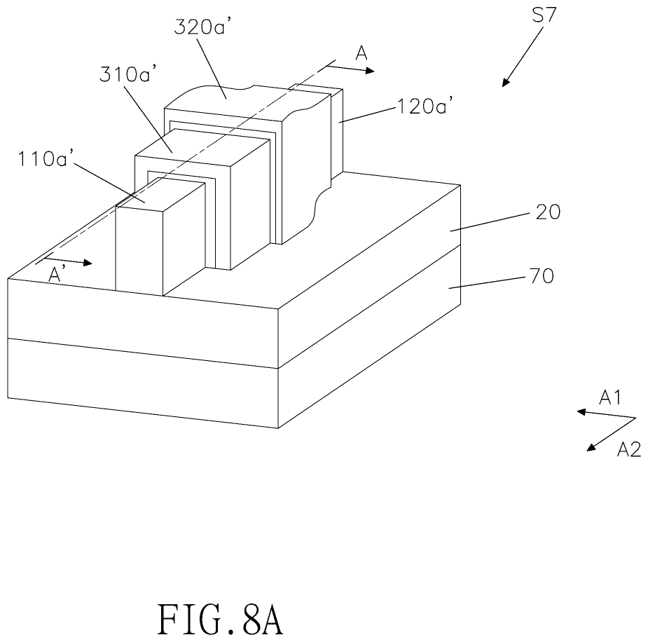

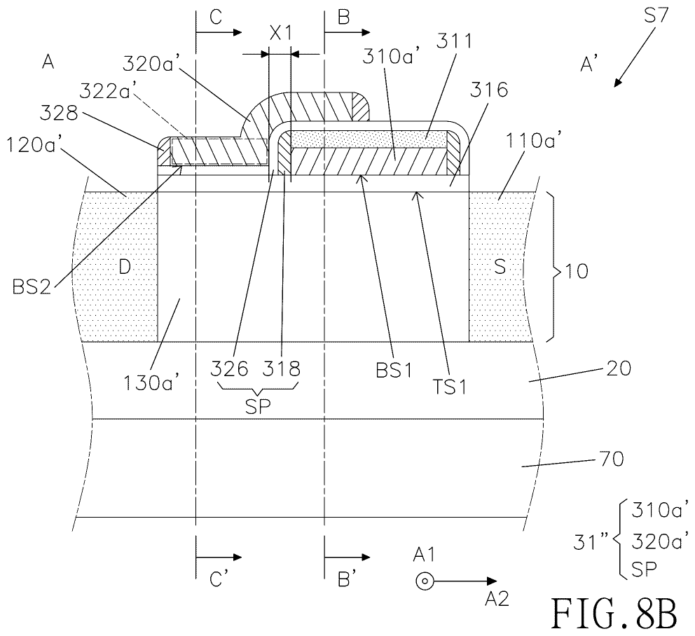

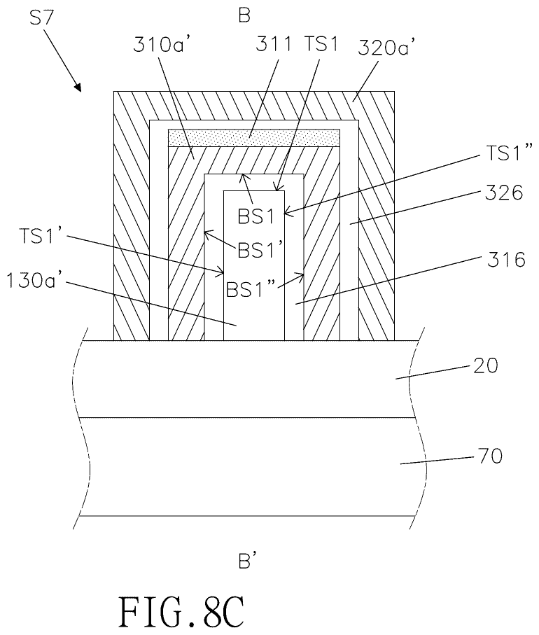

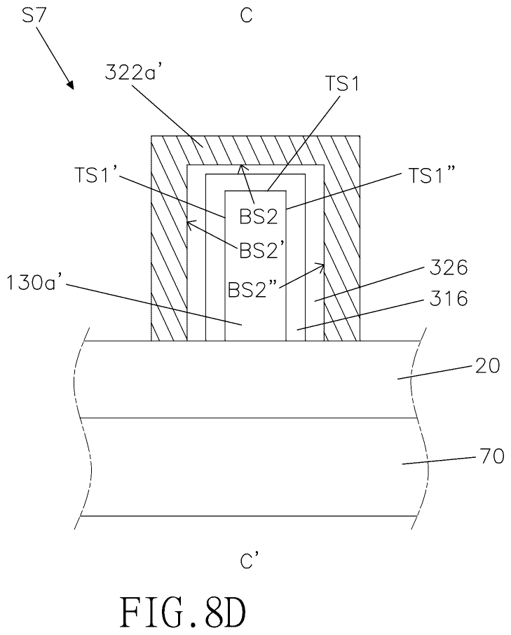

FIGS. 8A to 8D are schematic views to illustrate a semiconductor structure according to an embodiment of the present disclosure. FIG. 8A is a perspective view of a semiconductor structure S7, FIG. 8B is a cross-sectional view of the semiconductor structure S7 along line A-A′ in FIG. 8A, FIG. 8C is a cross-sectional view of the semiconductor structure S7 along line B-B′ in FIG. 8B, and FIG. 8D is a cross-sectional view of the semiconductor structure S7 along line C-C′ in FIG. 8B. Semiconductor structure S7 in FIGS. 8A to 8D may be substantially similar to semiconductor structure S1 in FIG. 1A where like reference numerals indicate like elements. As shown in FIGS. 8A to 8D, a first source region 110a′, a first drain region 120a′, and a first body region 130a′ are disposed in a fin structure of the semiconductor layer 10. The first body region 130a′ may be disposed between the first source region 110a′ and the first drain region 120a′. The first source region 110a′ is adjacent to one side of the first body region 130a′ such that a junction (not shown) may be formed therebetween, and the first drain region 120a′ is adjacent to an opposite side of the first body region 130a′ such that a junction (not shown) may be formed therebetween. The first source region 110a′ and the first drain region 120a′ may be similar to the first source region 110a and the first drain region 120a described above with reference to FIGS. 1A and 1B, and the first body region 130a′ may be similar to the first body region 130a described above with reference to FIGS. 1A and 1B.

In the embodiment shown in FIGS. 8A to 8D, the dual gate structure 31″ including a first gate 310a′, a second gate 320a′, and a spacing material SP. The dual gate structure 31″ surrounds the first body region 130a′ with two or more sides. In other words, the fin structure of the semiconductor layer 10 is wrapped around by the first gate 310a′ and the second gate 320a′. The first gate 310a′ and the second gate 320a′ may be similar to the first gate 310a and the second gate 320a described above with reference to FIGS. 1A and 1B.

Specifically, the second gate 320a′ may comprise a first horizontal section 322a′. The first horizontal section 322a′ may be an entire portion of the second gate 320a′ the bottom surface of which (e.g., the bottom surfaces BS2, BS2′, and BS2″) is substantially level relative to the surface of the first body region (e.g., the surface TS1, TS1′, TS1″ of the first body region 130a′ as shown in FIG. 8D). As shown in FIGS. 8D, the first horizontal section 322a′ of the second gate 320a′ may surround the first body region 130a′ with two or more sides.

The first horizontal section 322a′ of the second gate 320a′ may be laterally distanced from the first gate 310a′. In some embodiments, the lateral interval X1 between the edge of the bottom surface BS2 of the first horizontal section 322a′ of the second gate 320a′ and the edge of the bottom surfaces BS1, BS1′, BS1″ of the first gate 310a′ in the lateral direction (e.g., the second direction A2) may be in a range between 0.1 nm and 20 nm. In some embodiments, the lateral interval X1 may be in a range between 0.5 nm and 10 nm. In some embodiments, the lateral interval X1 may be in a range between 2 nm and 3 nm. However, these values are merely examples and are not intended to be limiting. Spacing material SP may be disposed between the first gate 310a′ and the first horizontal section 322a′ of the second gate 320a′. In the embodiment shown in FIGS. 8A to 8D, the spacing material SP may include dielectric material such as the first gate spacer 318 and/or the second gate dielectric 326. In some embodiments, the spacing material SP or a portion of the spacing material SP (e.g., the gate spacer) may be formed at a predetermined width, such that the lateral interval X1 between the first horizontal section 322a′ of the second gate 320a′ and the first gate 310a′ can be controlled. Other structural details of the semiconductor structure S1 described before may also apply here.

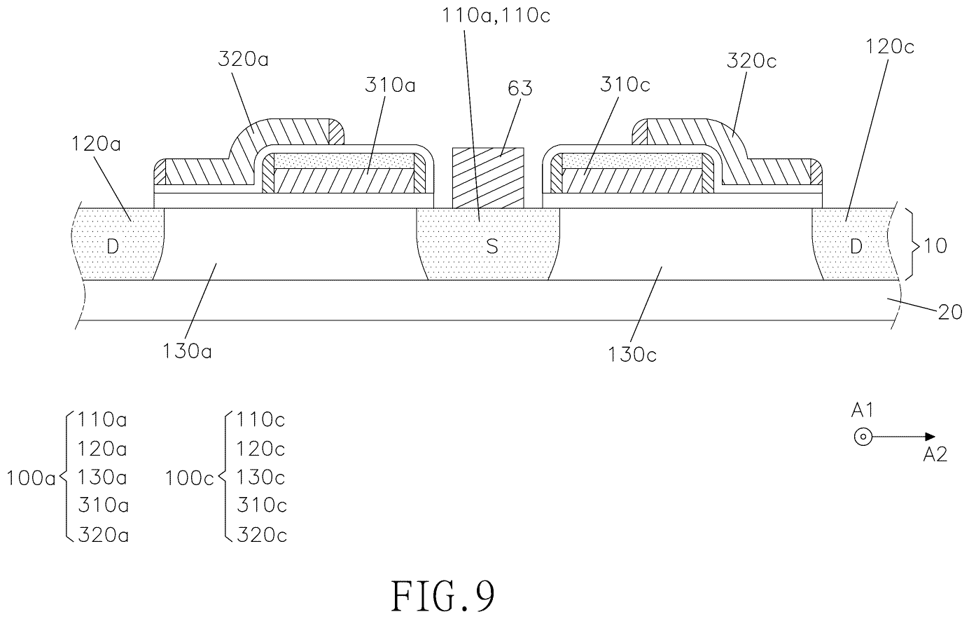

FIG. 9 is a schematic view to illustrate a portion of a memory array according to an embodiment of the present disclosure. The first memory cell 100a in FIG. 9 may be substantially similar to the first memory cell 100a in FIGS. 1C and 1D, and the third memory cell 100c in FIG. 9 may be substantially similar to the third memory cell 100c in FIGS. 1C and 1D, where like reference numerals indicate like elements. As shown in FIG. 9, the first source region 110a of the first memory cell 100a and the third source region 110c of the third memory cell 100c share a source contact 63. In some embodiments, the first memory cell 100a and the third memory cell 100c may share a common source region. As such, the size of the memory array can be reduced.

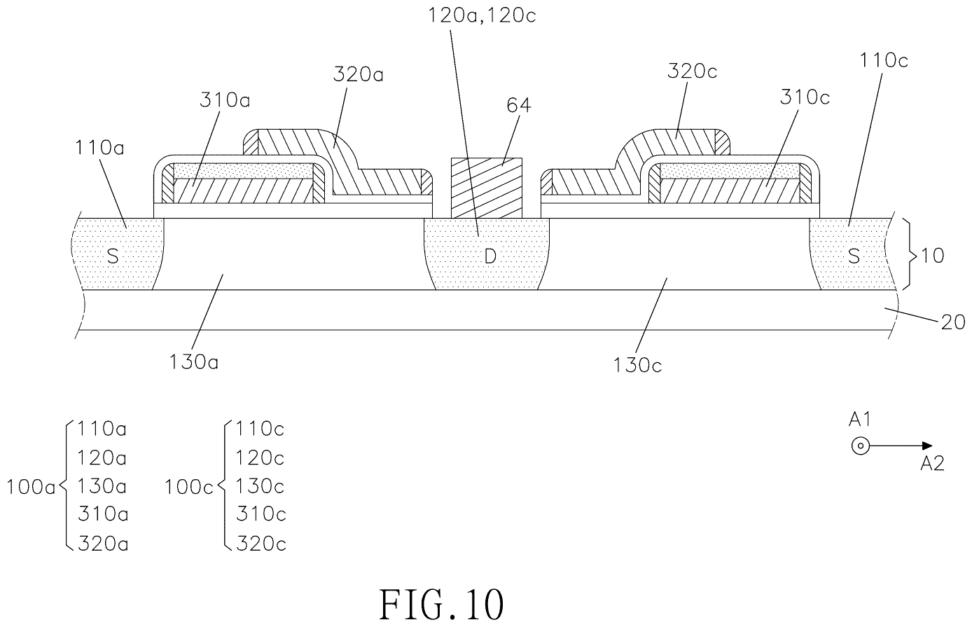

FIG. 10 is a schematic view to illustrate a portion of a memory array according to an embodiment of the present disclosure. The first memory cell 100a in FIG. 10 may be substantially similar to the first memory cell 100a in FIGS. 1C and 1D, and the third memory cell 100c in FIG. 10 may be substantially similar to the third memory cell 100c in FIGS. 1C and 1D, where like reference numerals indicate like elements. As shown in FIG. 10, the first drain region 120a of the first memory cell 100a and the third drain region 120c of the third memory cell 100c share a drain contact 64. In some embodiments, the first memory cell 100a and the third memory cell 100c may share a common drain region. As such, the size of the memory array can be reduced.

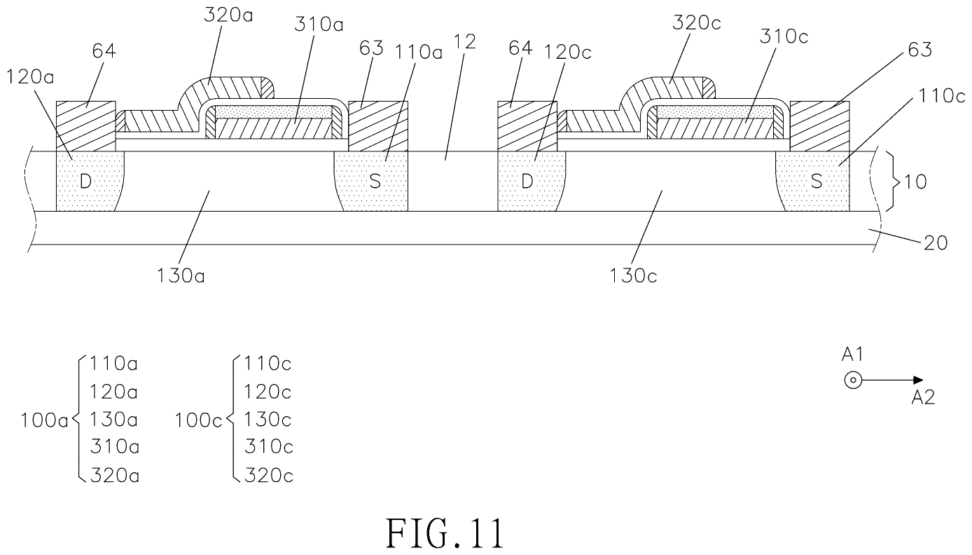

FIG. 11 is a schematic view to illustrate a portion of a memory array according to an embodiment of the present disclosure. The first memory cell 100a in FIG. 11 may be substantially similar to the first memory cell 100a in FIGS. 1C and 1D, and the third memory cell 100c in FIG. 11 may be substantially similar to the third memory cell 100c in FIGS. 1C and 1D, where like reference numerals indicate like elements. As shown in FIG. 11, the first memory cell 100a and the third memory cell 100c are spaced by isolation material 12.

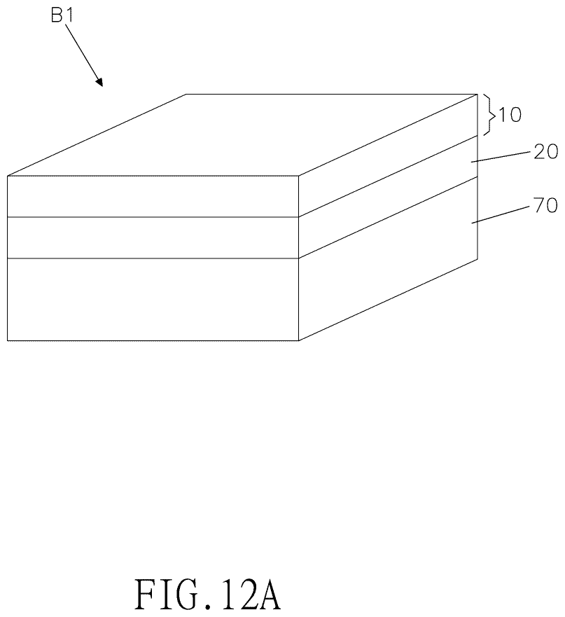

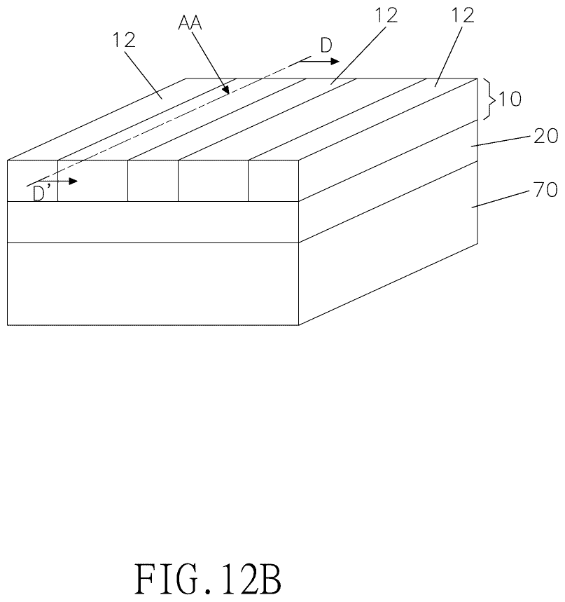

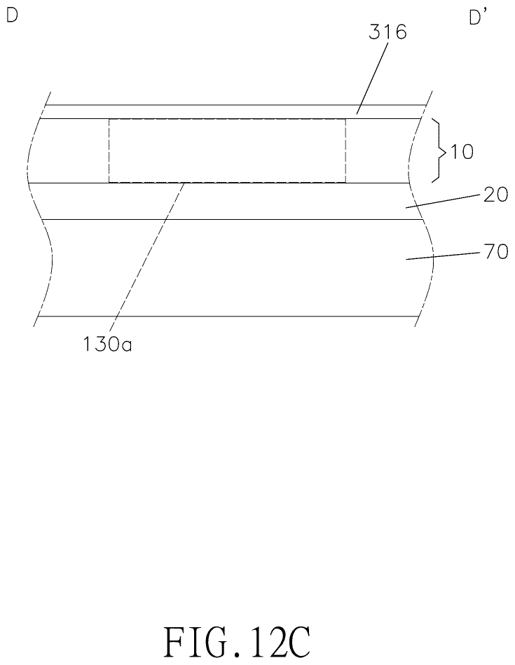

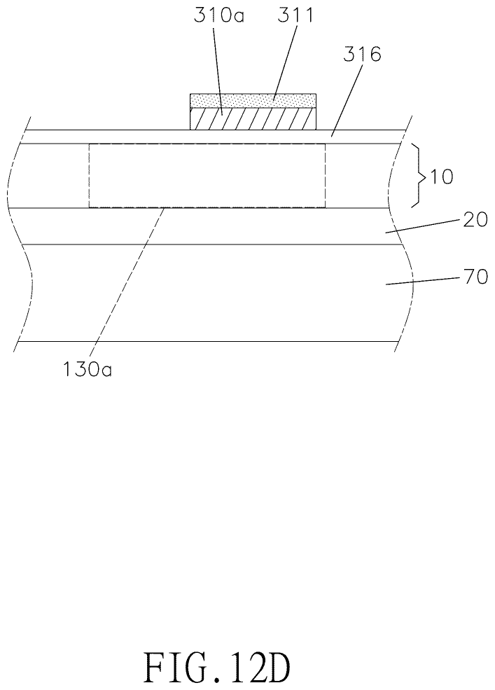

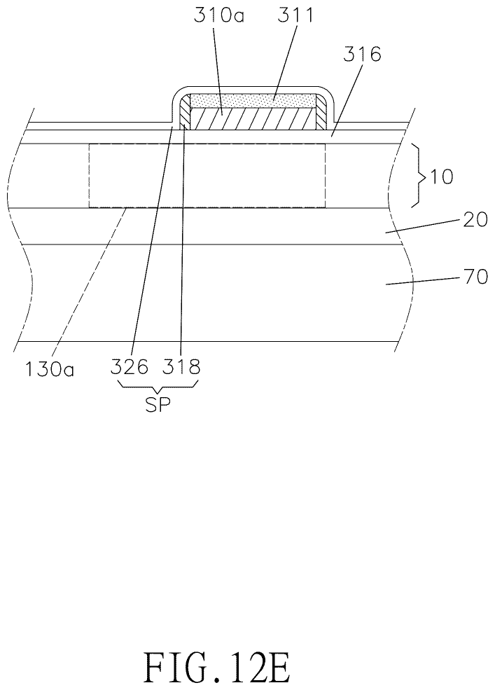

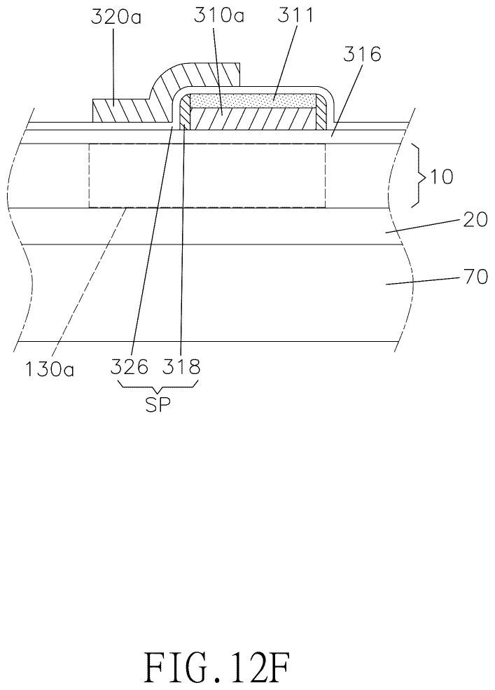

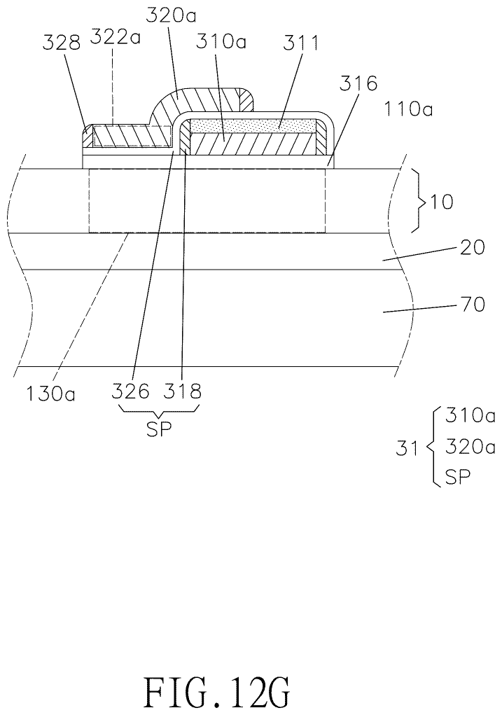

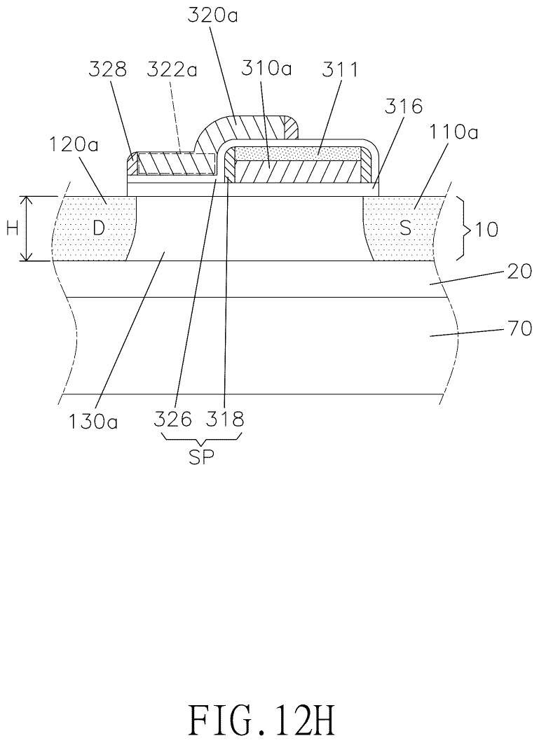

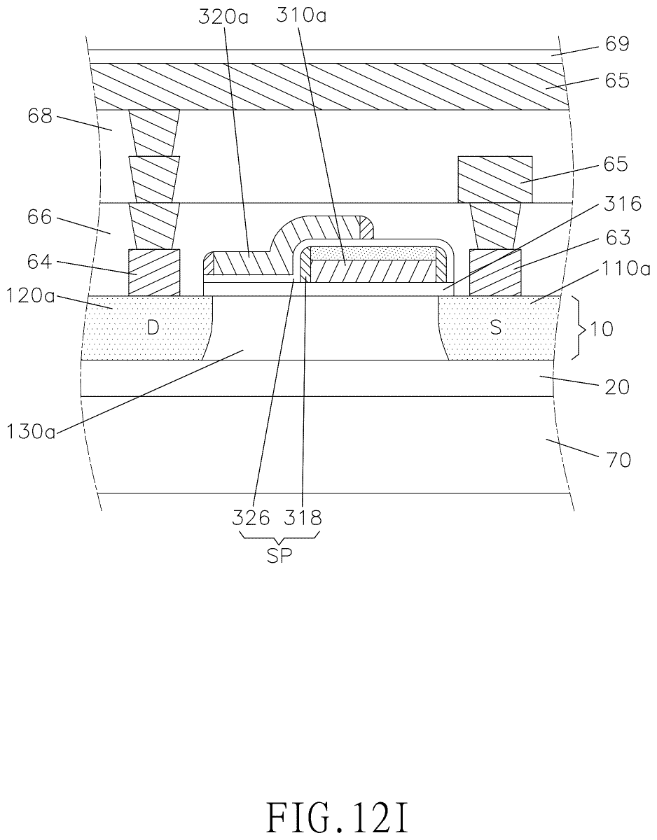

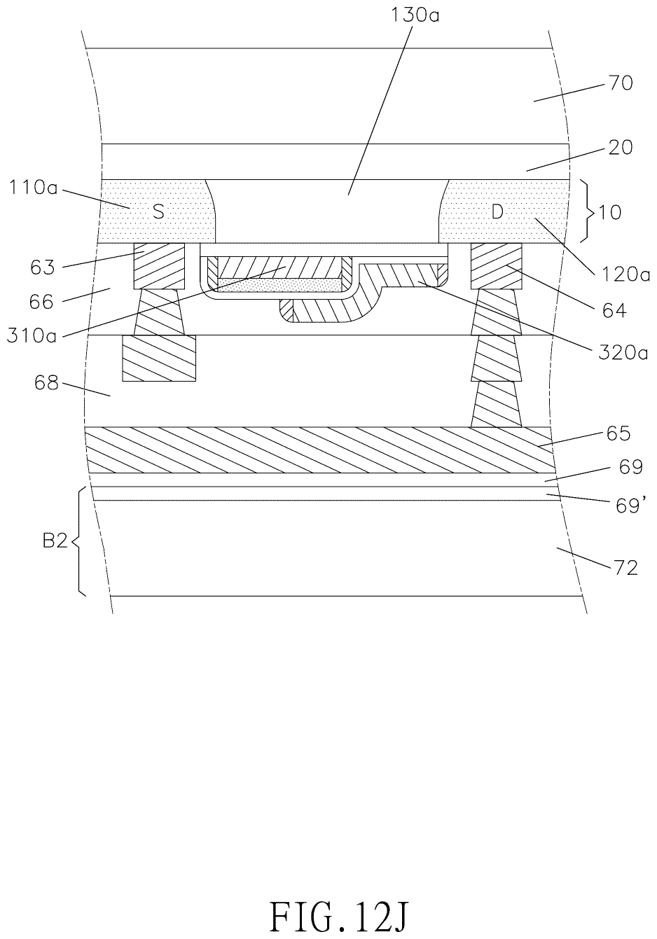

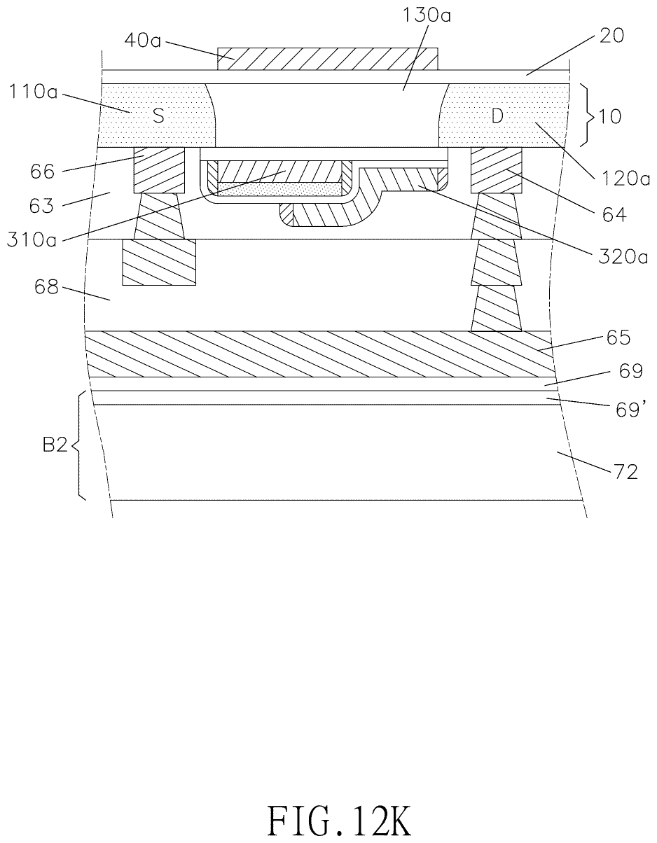

FIGS. 12A to 12K are schematic views to illustrate intermediate stages in the manufacture of a semiconductor structure according to an embodiment of the present disclosure. Specifically, FIGS. 12A to 12K illustrate a method for making a semiconductor structure similar to the semiconductor structures S1 to S7 describe above.

As shown in FIG. 12A, a first structure B1 including a first substrate 10 over a first dielectric layer 20 is received (step (a)). The first structure B1 may further include a second substrate 70, wherein the first dielectric layer 20 is disposed between the first substrate 10 and the second substrate 70. The first substrate 10 may comprise similar materials as discussed above for the semiconductor layer 10. In some embodiments, the first substrate 10 is a single crystalline substrate, for example, made of silicon, germanium, gallium arsenide (GaAs), indium phosphide (InP), silicon carbon (SiC), or gallium nitride (GaN). The second substrate 70 may be a single crystalline semiconductor substrate, for example, made of silicon, germanium, gallium arsenide (GaAs), or indium phosphide (InP), or a glass substrate. The first dielectric layer 20 may comprise silicon dioxide, although other dielectric materials are also possible. In the embodiment shown in FIG. 12A, the first structure B1 is a silicon-on-insulator (SOI) substrate. However, in other embodiments, the first structure B1 may be a silicon-metal-on-insulator (SMOI) substrate, a silicon-etch-stopper-on-insulator (SEOI) substrate, or a silicon-metal-etch-stopper-on-insulator (SMEOI) substrate. In the embodiment shown in FIG. 12A, the first dielectric layer 20 may be the insulator (e.g., silicon oxide) of the SOI substrate.

Next, defining an active area AA in the first substrate 10 (step (b)), for example, by etching a portion of the first substrate 10 to expose the first dielectric layer 20 and forming isolation structures 12 in the etching trenches, as shown in FIG. 12B. The isolation structures 12 may include a dielectric material, such as silicon oxide, spin-on-glass, silicon nitride, silicon oxynitride, fluorine-doped silicate glass (FSG), a low-k dielectric material, other suitable insulating material, and combinations thereof. The isolation structures 12 may be shallow trench isolation (STI) structures formed through conventional processes.

FIGS. 12C to 12K illustrates a cross-sectional view along line D-D′ in FIG. 12B. Referring to FIG. 12C, a first body region 130a in a predetermined region in the active area AA in the first substrate 10 is doped with a first type of material. In some embodiments, the first type of material may be p-type dopants described above. In some embodiments, the first type of material may be n-type dopants described above. The first body region 130a may be doped with a first type of material before the formation of the dual gate structure, i.e., the step (c). The first body region 130a may be formed using suitable implantation processes. A patterned masking layer (e.g., photoresist material) may be formed on the first substrate 10 and an ion implantation process may be used to dope regions of the first substrate 10 exposed by the patterned masking layer. However, in some embodiments, the predetermined region for the first body region 130a may be doped before the formation of the isolation structures 12 or before the receiving of the first structure B1.

Next, a first gate dielectric 316 may be formed over the first substrate 10. The first gate dielectric 316 may be deposited on the first substrate 10 and on the first body region 130a. The first gate dielectric 316 may be formed by chemical vapor deposition (CVD), atomic layer deposition (ALD), physical vapor deposition (PVD), sputtering, e-beam evaporation, or any other suitable deposition process.

Referring to FIG. 12D, a first gate 310a over the first gate dielectric 316 is formed (step (c1)). Silicon gate material may be deposited on a top surface of the first gate dielectric 316. In some embodiments, the silicon gate material can be formed using polycrystalline silicone, single crystalline silicon, or any suitable material. In some embodiments, the silicon gate material can be formed using amorphous silicon material. The silicon gate material can be deposited using CVD, PVD, sputtering, e-beam evaporation, any suitable deposition methods, and/or combinations thereof. In some embodiments, the silicon gate material is heavily doped to improve its conductivity. The silicon gate material may be patterned and etched to form the first gate 310a. As shown in FIG. 12D, the first gate 310a is formed on the first gate dielectric 316 after a patterning process. In some embodiments, the patterning process can include forming a dielectric hard mask 311 on the silicon gate material. In some embodiments, the dielectric hard mask 311 may be removed using suitable removal processes (e.g., etching processes) after the first gate 310a is formed; however, in the embodiment shown in FIGS. 12A to 12K, the dielectric hard mask 311 remains on the first gate 310a throughout the process.

Referring to FIG. 12E, spacing material SP is formed on a sidewall of the first gate 310a (step (c2)). As shown in FIG. 12E, first gate spacers 318 are formed on the sidewalls of the first gate 310a. The first gate spacers 318 can be formed using a deposition process followed by one or more etching or planarization processes. For example, a blanket layer of dielectric material can be deposited on the exposed surface of the first gate dielectric 316 and on the sidewalls and the top surface of the first gate 310a. In some embodiments, the blanket layer of dielectric material can be deposited using ALD, CVD, PVD, sputtering, e-beam evaporation, spin-on application, any suitable deposition methods, and/or combinations thereof. One or more etching processes can remove portions of the blanket layer of dielectric material from the top surface of the first gate dielectric 316 such that the first gate spacers 318 can be formed. As shown in FIG. 12E, the first gate spacers 318 may also be formed on the sidewalls of the hard mask 311. In some embodiments, a gate replacement process can be further implemented to form a first gate comprising a metal gate stack. In some embodiments, a portion of the first gate dielectric 316 may be etched during one or more of the etching processes, such that the portion of the first gate dielectric 316 uncovered by the first gate 310a may be thinner or removed.

As shown in FIG. 12E, a second gate dielectric 326 is formed on the first gate dielectric 316, the first gate spacers 318, and the hard mask 311. The second gate dielectric 326 may be formed by similar method as discussed above for the first gate dielectric 316. As such, the spacing material SP including a portion of the first gate spacer 318 and/or a portion of the second gate dielectric 326 may be formed on the sidewall of the first gate 310a. In some embodiments, the first gate spacers 318 may be omitted, and the second gate dielectric 326 may be formed on a sidewall of the first gate 310a. In some embodiments, a second gate dielectric may be omitted, and the first gate 310a and the second gate 320a may be spaced by the first gate spacers 318 and the dielectric mask 311.

Referring to FIG. 12F, a second gate 320a is formed adjacent to the spacing material SP such that the first gate 310a and the second gate 320a are spaced apart by the spacing material SP (step (c4)). The second gate 320a may be formed by similar method as discussed above for the first gate 310a. Specifically, silicon gate material may be deposited and etched to form a second gate 320a.

Referring to FIG. 12G, second gate spacers 328 are formed on the sidewalls of the second gate 320a. The second gate spacers 328 may be formed by similar method as discussed above for the first gate spacers 318. As shown in FIG. 12G, the exposed portions of the first gate dielectric 316 is removed. In some embodiments, the exposed portions of the first gate dielectric 316 may be removed during the formation of the second gate spacers 328. In some embodiments, a gate replacement process can be further implemented to form a second gate comprising a metal gate stack. Through processes described above with regard to FIGS. 12C to 12G, a dual gate structure 31 including a first gate 310a, a second gate 320a and a spacing material SP may be formed over the first substrate 10, wherein the second gate 320a comprises a first horizontal section 322a laterally distanced from the first gate 310a, and the spacing material SP is disposed laterally between the first gate 310a and the first horizontal section 322a of the second gate 320a (step (c)).

Next, referring to FIG. 12H, a first source region 110a and a first drain region 120a are formed in the active area AA (step (d)). The first source region 110a and a first drain region 120a may be formed by doping predetermined regions in the active area AA with a second type of material, which is different conductivity type from the first type of material. In some embodiments, a self-aligned ion implantation process may be performed. For example, an ion implantation process can be implemented to inject the second type of material into predetermined regions of the active area AA. The first gate 310a, the second gate 320a, the first gate spacer 318, and the second gate spacer 328 may act as an ion implantation mask, and the first source region 110a and the first drain region 120a may be self-aligned. As such, in the embodiment shown in FIG. 12H, the first source region 110a is formed adjacent to the first gate 310a and an edge of the first source region 110a is approximately aligned to an end of the first gate 310a, and the first drain region 120a is formed adjacent to the first horizontal section 322a of the second gate 320a and an edge of the first drain region 120a is approximately aligned to an end of the first horizontal section 322a of the second gate 320a. The ion implantation process may be performed under certain energy level such that the first source region 110a and the first drain region 120a are formed extending through the thickness H of the first substrate 10. In some embodiments, the first source region 110a and a first drain region 120a may be formed through epitaxy process.

As shown in FIG. 12I, a source contact 63 is formed on the first source region 110a and a drain contact 64 is formed on the first drain region 120a. The source contact 63 is electrically coupled to the first source region 110a, and the drain contact 64 is electrically coupled to the first drain region 120a. Conductive wires 65 electrically connecting to the contacts including the source contact 63 and/or the drain contact 64 may also be formed. The source contact 63 and the drain contact 64 are deposited in dielectric layers 66, and the conductive wires 65 are deposited in dielectric layers 68. The dielectric layers 66 and 68 can be interlayer dielectric (ILD) layers and/or inter-metal dielectric (IMD) formed above the first substrate 10. In some embodiments, the dielectric layers 66 and 68 can be formed using silicon oxide and deposited using CVD, PVD, sputtering, any suitable deposition processes, and/or combinations thereof. In some embodiments, the dielectric layers 66 and 68 can be formed using any suitable low-k dielectric material. In some embodiments, the source contact 63 and the drain contact 64 can be formed using conductive materials, such as copper, cobalt, aluminum, tungsten, ruthenium, any suitable conductive material, and combinations thereof. In some embodiments, the source contact 63, the drain contact 64, and the conductive wires 65 can be formed using a damascene or dual damascene process. A bonding layer 69 may also be formed over the dielectric layers 68 and the conductive wires 65, such that the dielectric layers 68 are disposed between the bonding layer 69 and the first substrate 10. The bonding layer 69 may comprise at least one dielectric sublayer, such as an oxide layer, and may be formed by deposition such as CVD or PVD.

Referring to FIG. 12J, a second structure B2 is provided. The second structure B2 comprises a third substrate 72. The third substrate 72 may comprise similar materials as described for the second substrate 70. In some embodiments, the third substrate 72 contains multiple electronic devices including at least one of transistors, diodes, capacitors, and resistors. Next, the first substrate 10 is flipped and bonded onto the second structure B2 by the bonding layer 69 to form a bonded structure as shown in FIG. 12J. The bonding between the bonding layer 69 and the second structure B2 may be direct bonding, e.g., fusion bonding. The bonding process involves pressing the bonding layer 69 and the second structure B2 against each other and performing an annealing process to cause the bonding layer 69 and the second structure B2 to be bonded together due to atomic attraction forces. In some embodiments, a bonding layer 69′ similar to the bonding layer 69 may be formed on the third substrate 72 before bonding. In some other embodiments, the bonding layer 69 may not be formed on the dielectric layers 68, and the bonding occurs between the dielectric layers 68 and the second structure B2.

As shown in FIG. 12K, the second substrate 70 is removed from the bonded structure (step (f)). In one embodiment, a chemical mechanical polishing (CMP) operation is performed to remove the second substrate 70. Other approaches such as etching may be used for the same purpose. In such embodiment, the first dielectric layer 20 may act as an etch stop layer, or an etch stop layer may need to be deposited in advance. The second substrate 70 may be completely removed from the bonded structure after step (f). In some embodiments, a portion of the first dielectric layer 20 may also be removed, e.g., through suitable grinding process such as CMP operation.

Then, a back gate 40a may be formed on the first substrate 10 and on the first dielectric layer 20, wherein the first substrate 10 is between the dual gate structure 31 and the back gate 40a (step (g)). The back gate 40a may comprise similar materials and formation methods as described for the first gate 310a. Specifically, a layer of conductive gate material may be patterned and etched to form the back gate 40a. In some embodiments, the back gate 40a may be formed of conductive materials and may be formed by similar methods described above with reference to FIGS. 1A and 12D for the first gate 310a. The first gate contact (e.g., the first gate contact 61 shown in FIGS. 1C, 5B, and 6B) may also be formed after the removal of the second substrate 70. In some other embodiments, instead of forming the source contact 63 and the drain contact 64 on the same side of the first substrate 10 as the dual gate structure 31 (as shown in FIG. 12I), at least one of the source contact and the drain contact, as well as the conductive wires electrically connected thereto, can be formed after the removal of the second substrate 70.

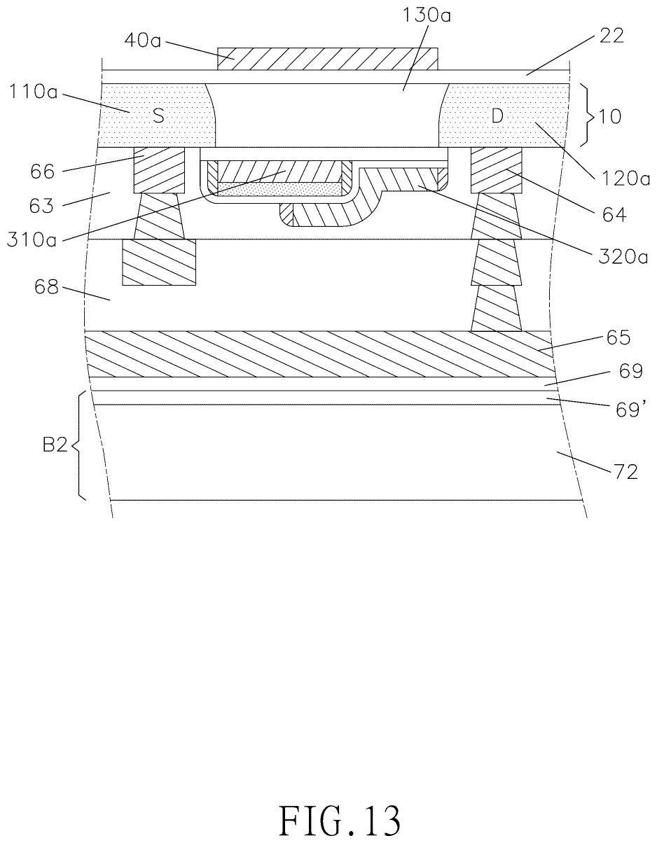

FIG. 13 is a schematic cross-sectional view to illustrate an intermediate stage in the manufacture of a semiconductor structure according to an embodiment of the present disclosure. In the embodiment shown in FIG. 13, after the removal of the second substrate 70 (step (f)), the first dielectric layer 20 may also be completely removed through suitable grinding process such as CMP operation or suitable etching process. Then, a dielectric layer 22 may be formed on the exposed surface of the first substrate 10, and a back gate 40a may be formed on the first substrate 10 and on the dielectric layer 22, wherein the first substrate 10 is between the dual gate structure 31 and the back gate 40a (step (g)). The dielectric layer 22 may comprise similar materials and formation methods as described for the first gate dielectric 316.

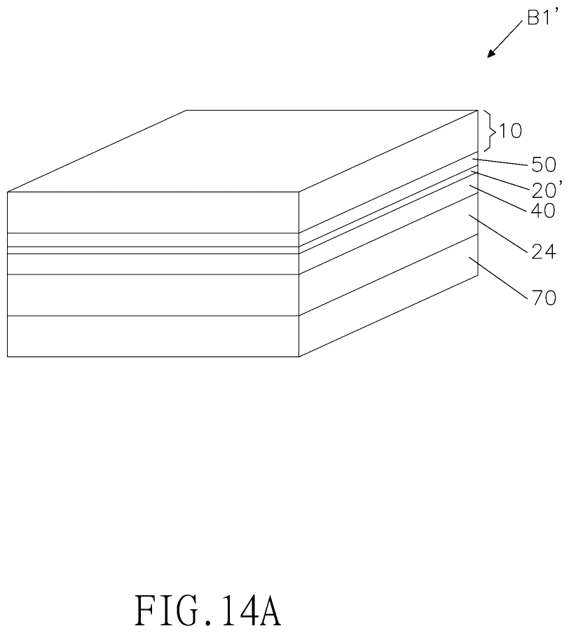

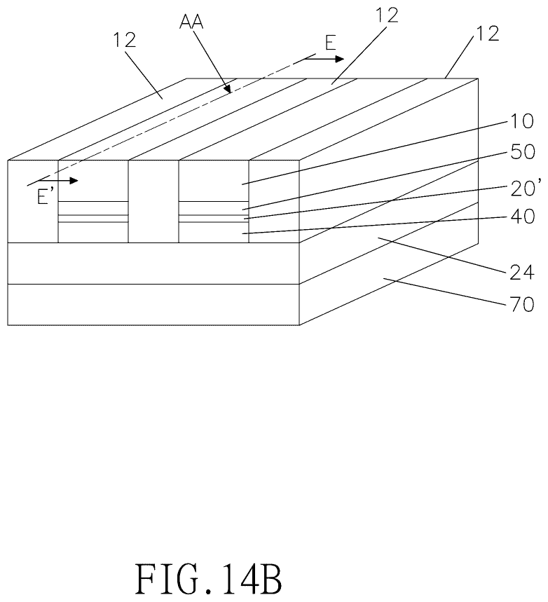

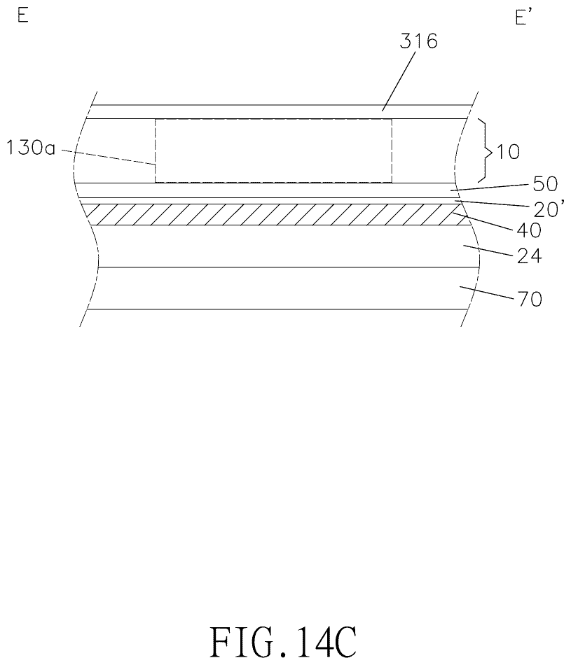

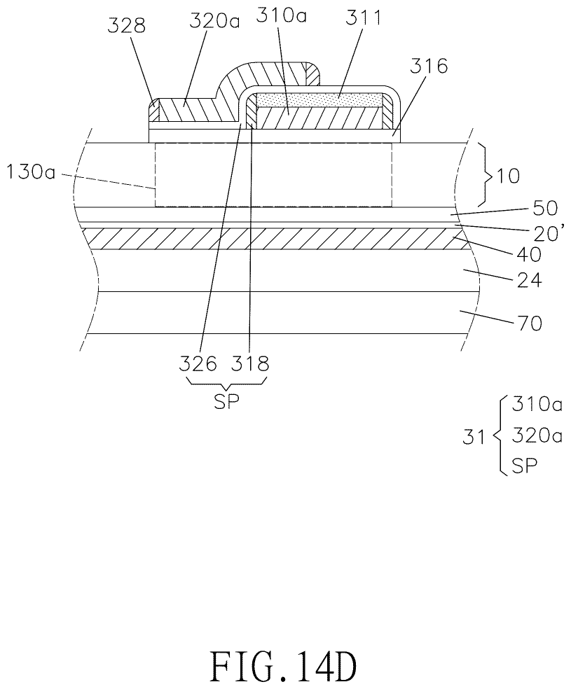

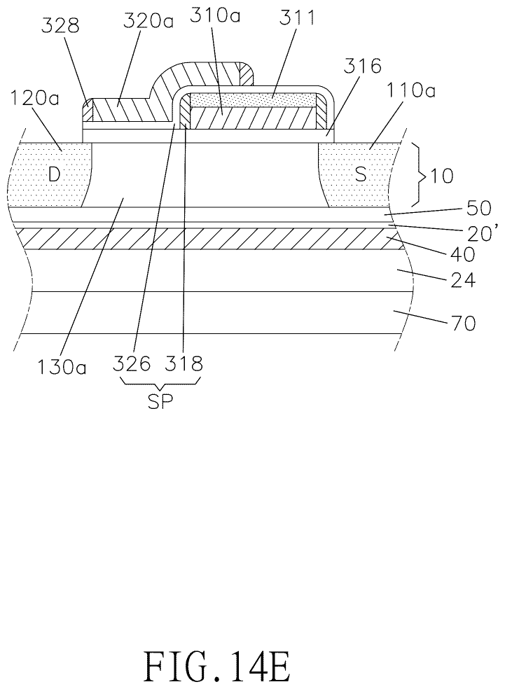

FIGS. 14A to 14E are schematic views to illustrate intermediate stages in the manufacture of a semiconductor structure according to an embodiment of the present disclosure. Specifically, FIGS. 14A to 14E illustrate a method for making a semiconductor structure similar to the semiconductor structures S1 to S7 describe above.

Referring to FIG. 14A, a first structure B1′ is received (step (a)). The first structure B1′ may comprise a first substrate 10 and a second dielectric layer 24, wherein the first substrate 10 is disposed over the second dielectric layer 24. The first structure B1′ may further include a second substrate 70, wherein the second dielectric layer 24 is disposed between the first substrate 10 and the second substrate 70. As shown in FIG. 14A, the first structure B1′ may further include a conductive layer 40 and a first dielectric layer 20′, wherein the first dielectric layer 20′ is disposed between the first substrate 10 and the conductive layer 40, and the conductive layer 40 is disposed between the first dielectric layer 20′ and the second dielectric layer 24. The conductive layer 40 may include one or a plurality of conductive material layers and may be patterned or unpatterned. As shown in FIG. 14A, in some embodiments, the first structure B1′ may further include a charge storage layer 50 between the first substrate 10 and the first dielectric layer 20′. The first substrate 10 and the second substrate 70 may be similar to the first substrate 10 and the second substrate 70 described above with regard to FIG. 12A, respectively. The first dielectric layer 20′ and the second dielectric layer 24 may comprise similar materials as described for the first dielectric layer 20 with regard to FIGS. 1A and 12A. In some other embodiments, the first structure B1′ may be provided without conductive layer 40 or the charge storage layer 50.

Next, defining an active area AA in the first substrate 10 (step (b)). As shown in FIG. 14B, defining the active area AA may include one or more etching process to remove a portion of the first substrate 10, the charge storage layer 50, the first dielectric layer 20′, and the conductive layer 40 to expose the second dielectric layer 24. The etching process(es) may be performed with suitable etchant(s). Then, isolation structures 12 are formed in the etching trenches. The isolation structures 12 may comprise similar materials and formation methods as described with regard to FIG. 12B. In some embodiments, the conductive layer 40 may be patterned after removal of a portion of the conductive layer 40.

FIGS. 14C to 14E illustrates a cross-sectional view along line E-E′ in FIG. 14B. Referring to FIG. 14C, a first body region 130a in a predetermined region in the active area AA in the first substrate 10 is doped with a first type of material, and a first gate dielectric 316 is formed over the first substrate 10, as described above with regard to FIG. 12C. The first body region 130a may be doped with a first type of material before the formation of the dual gate structure, i.e., the step (c).

Referring to FIG. 14D, the dual gate structure 31 including a first gate 310a, a second gate 320a and a spacing material SP may be formed by methods described above with regard to FIGS. 12D to 12G (step (c)). Then, as shown in FIG. 14E, a first source region 110a and a first drain region 120a may be formed in the active area AA by methods described above with regard to FIG. 12H (step (d)).

The semiconductor structures, memory arrays, and manufacturing methods thereof described above has one or more of the following advantages.
1. The semiconductor structures according to some embodiments of the present disclosure may include a semiconductor layer over a first dielectric layer, and a dual gate structure over a body region in the semiconductor layer. As such, the semiconductor structures can be controlled by the first gate and the second gate to generate and stored charges in the body region in the semiconductor layer. Moreover, the semiconductor structures may be operated under relatively small voltages and current, which may be advantageous when a plurality of the semiconductor structures are connected in series. Also, the size of the semiconductor structures can be scaled down.
2. The memory arrays according to some embodiments of the present disclosure may include a first memory cell and a second memory cell each including a first gate, a second gate, and a drain region in the semiconductor layer over a first dielectric layer; wherein the first gate of the first memory cell and the second memory cell are electrically connected, and the second gate of the first memory cell and the second memory cell are electrically connected. As such, the first memory cell and the second memory cell can be operated as a 1T0C memory cell through the signal voltages applied to the first gate, the second gate, and the drain region. Moreover, the read margin of the memory cells can be enhanced compared to at least some of the current 1T0C memory cells. Also, the size of the memory cells can be scaled down.
3. The semiconductor structures and the memory arrays according to some embodiments of the present disclosure may function without additional capacitor. As such, it is easier for the semiconductor structures and the memory arrays to be scaled down, and the manufacturing process of the semiconductor structures and the memory arrays may be compatible with that of other portions of circuits (e.g., a CPU).
4. The semiconductor structures and the memory arrays according to some embodiments of the present disclosure may be able to function under a consistent and controllable electric field. As such, the behavior of the semiconductor structures and the memory cell may be more consistent and controllable.
5. According to some embodiments of the present disclosure, the second gate in the semiconductor structures and the memory arrays can be configured as a “step-shaped” structure. As such, the size of the semiconductor structure and/or the memory cells may be reduced.
6. According to some embodiments of the present disclosure, in the semiconductor structures and the memory arrays, the first gate may be disposed laterally between the first source region and the first horizontal section of the second gate. As such, more charge can be stored in the body region of the semiconductor structure and/or the memory cells.
7. According to some embodiments of the present disclosure, in the semiconductor structures and the memory arrays, threshold voltages of the first gate may be smaller than threshold voltage of the second gate. As such, it may be easier to provide proper operational conditions for the semiconductor structure and/or the memory cells.
8. According to some embodiments of the present disclosure, the memory arrays may be easily operated by operational conditions as described herein.
9. The methods according to some embodiments of the present disclosure may provide processes through which the semiconductor structures and/or the memory arrays described herein can be provided.

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter. Thus, it is intended that the present disclosure covers modifications and variations that come within the scope of the appended claims and their equivalents.

1. A semiconductor structure, comprising:
a first dielectric layer;
a semiconductor layer over the first dielectric layer, the semiconductor layer comprising a source region, a drain region, and a body region between the source region and the drain region; and
a dual gate structure over the body region;
wherein the dual gate structure comprises:
a first gate;
a second gate comprising a first horizontal section laterally distanced from the first gate; and
a spacing material between the first gate and the first horizontal section of the second gate.

2. The semiconductor structure of claim 1 further comprising a first gate contact and a second gate contact, wherein the first gate contact is electrically connected to the first gate, and the second gate contact is electrically connected to the second gate.

3. The semiconductor structure of claim 1, wherein both the source region and the drain region are in contact with the first dielectric layer.

4. The semiconductor structure of claim 1, wherein a thickness of the semiconductor layer is in a range between 3 nm and 200 nm.

5. The semiconductor structure of claim 1, wherein a lateral interval between the first horizontal section of the second gate and the first gate is in a range between 0.1 nm and 20 nm.

6. The semiconductor structure of claim 1, wherein a first distance between a bottom surface of the first gate and a top surface of the semiconductor layer is smaller than a second distance between a bottom surface of the first horizontal section of the second gate and the top surface of the semiconductor layer.

7. The semiconductor structure of claim 1, wherein the second gate further comprises a second horizontal section and a connection section connecting the first horizontal section and the second horizontal section, and the second horizontal section is disposed above and overlapped with the first gate.

8. The semiconductor structure of claim 7, wherein a second distance between a bottom surface of the first horizontal section of the second gate and a top surface of the semiconductor layer is smaller than a third distance between a bottom surface of the second horizontal section of the second gate and the top surface of the semiconductor layer.

9. The semiconductor structure of claim 1, wherein the source region is adjacent to the first gate, and the drain region is adjacent to the first horizontal section of the second gate.

10. The semiconductor structure of claim 1, wherein the first gate overlaps a first portion of the body region from a top view, and the first horizontal section of the second gate overlaps a second portion of the body region from a top view.

11. The semiconductor structure of claim 1, wherein the first gate is between the source region and the first horizontal section of the second gate.

12. The semiconductor structure of claim 1, wherein a first length of the first gate is greater than a second length of the first horizontal section of the second gate.

13. The semiconductor structure of claim 1 further comprising a charge storage layer between the semiconductor layer and the first dielectric layer, wherein the charge storage layer is in contact with the semiconductor layer.

14. The semiconductor structure of claim 13, wherein the charge storage layer is either a polysilicon layer, a silicon nitride layer, or a silicon oxynitride layer.

15. The semiconductor structure of claim 13, wherein both the source region and the drain region are in contact with the charge storage layer.

16. The semiconductor structure of claim 1 further comprising a back gate, wherein the first dielectric layer is between the back gate and the semiconductor layer.

17. The semiconductor structure of claim 16 further comprising a charge storage layer between the semiconductor layer and the first dielectric layer, wherein the charge storage layer is in contact with the semiconductor layer.

18. The semiconductor structure of claim 1, wherein the dual gate structure surrounds the body region with two or more sides.

19. The semiconductor structure of claim 2, wherein the first gate contact is disposed on a bottom side of the first gate.

20. A memory array, comprising:
a first dielectric layer;
a semiconductor layer over the first dielectric layer, and
a first column of memory cell comprising a first memory cell and a second memory cell arranged in a first direction, wherein each of the first memory cell and the second memory cell comprises a source region in the semiconductor layer, a drain region in the semiconductor layer, a body region in the semiconductor layer between the source region and the drain region, and a first gate and a second gate over the body region, wherein the second gate of the first memory cell comprises a first horizontal section laterally distanced from the first gate of the first memory cell, the second gate of the second memory cell comprises a first horizontal section laterally distanced from the first gate of the second memory cell, and wherein the first gate of the first memory cell is electrically connected to the first gate of the second memory cell, and the second gate of the first memory cell is electrically connected to the second gate of the second memory cell.

21. The memory array of claim 20, wherein the second gate of the first memory cell further comprises a second horizontal section and a connection section connecting the first horizontal section of the first memory cell and the second horizontal section of the first memory cell, and the second horizontal section of the second gate of the first memory cell is disposed above and overlapped with the first gate of the first memory cell.

22. The memory array of claim 20, wherein both the body region of the first memory cell and the body region of the second memory cell are floating.

23. The memory array of claim 20, wherein a first threshold voltage of the first gate of the first memory cell is smaller than a second threshold voltage of the second gate of the first memory cell.

24. The memory array of claim 20, wherein the first gate of the first memory cell is electrically connected to a first word line of the first column, the second gate of the first memory cell is electrically connected to a second word line of the first column, and the drain region of the first memory cell is electrically connected to a first bit line.

25. The memory array of claim 20, wherein the first gate of the second memory cell is electrically connected to a first word line of the first column, the second gate of the second memory cell is electrically connected to a second word line of the first column, and the drain region of the second memory cell is electrically connected to a second bit line.

26. The memory array of claim 20, wherein when the first memory cell is not selected, zero voltage is applied to the first gate of the first memory cell, zero voltage is applied to the second gate of the first memory cell, and zero voltage is applied to the drain region of the first memory cell.

27. The memory array of claim 20, wherein when the first memory cell is selected for writing, a first voltage is applied to the first gate of the first memory cell, a second voltage is applied to the second gate of the first memory cell, and a third voltage is applied to the drain region of the first memory cell, wherein each of the first voltage, the second voltage, and the third voltage is positive.

28. The memory array of claim 20, wherein when the first memory cell is selected for writing, a first channel and a second channel are formed in the body region of the first memory cell; wherein the first channel is overlapped with the first gate of the first memory cell, the second channel is overlapped with the first horizontal section of the second gate of the first memory cell, and the first channel is discontinuous with the second channel.

29. The memory array of claim 20, wherein when the first memory cell is selected for erasing, a first voltage is applied to the first gate of the first memory cell, a second voltage is applied to the second gate of the first memory cell, and zero voltage is applied to the drain region of the first memory cell, wherein both the first voltage and the second voltage are positive.

30. The memory array of claim 20, wherein when the first memory cell is selected for reading, zero voltage is applied to the first gate of the first memory cell, a fourth voltage is applied to the second gate of the first memory cell, and a fifth voltage is applied to the drain region of the first memory cell, wherein both the fourth voltage and the fifth voltage are positive.

31. The memory array of claim 20, wherein each of the first memory cell and the second memory cell further comprises a back gate, wherein the back gate of the first memory cell is overlapped with the body region of the first memory cell, the back gate of the second memory cell is overlapped with the body region of the second memory cell, the first dielectric layer is disposed between the body region of the first memory cell and the back gate of the first memory cell, and the first dielectric layer is disposed between the body region of the second memory cell and the back gate of the second memory cell.

32. The memory array of claim 31, wherein the back gate of the first memory cell is electrically connected to the back gate of the second memory cell.

33. The memory array of claim 31, wherein the back gate of the first memory cell is electrically connected to a third word line of the first column.

34. The memory array of claim 31, wherein when the first memory cell is not selected, a sixth voltage is applied to the back gate of the first memory cell, wherein the sixth voltage is negative.

35. The memory array of claim 31, wherein when the first memory cell is selected for writing, a sixth voltage is applied to the back gate of the first memory cell, wherein the sixth voltage is negative.

36. The memory array of claim 31, wherein when the first memory cell is selected for erasing, zero voltage is applied to the back gate of the first memory cell.

37. The memory array of claim 31, wherein when the first memory cell is selected for reading, zero voltage is applied to the back gate of the first memory cell.

38. The memory array of claim 20, wherein a lateral interval between the first horizontal section of the second gate of the first memory cell and the first gate of the first memory cell is in a range between 0.1 nm and 20 nm.

39. The memory array of claim 20 further comprising a second column of memory cell, wherein the second column of memory cell comprises a third memory cell comprising a source region in the semiconductor layer, a drain region in the semiconductor layer, a body region in the semiconductor layer between the source region and the drain region, and a first gate and a second gate over the body region, wherein the second gate of the third memory cell comprises a first horizontal section laterally distanced from the first gate of the third memory cell; and wherein the first memory cell and the third memory cell are arranged in a second direction different from the first direction.

40. The memory array of claim 39, wherein the first gate of the third memory cell is electrically connected to a first word line of the second column, the second gate of the third memory cell is electrically connected to a second word line of the second column, and the drain region of the third memory cell is electrically connected to a first bit line.

41. The memory array of claim 39, wherein the source region of the first memory cell and the source region of the third memory cell share a source contact.

42. The memory array of claim 39, wherein the drain region of the first memory cell and the drain region the first memory cell share a drain contact.

43. The memory array of claim 39, wherein the first memory cell and the third memory cell are spaced by isolation material.

44. The memory array of claim 39, wherein each of the first memory cell and the third memory cell further comprises a back gate, wherein the back gate of the first memory cell is overlapped with the body region of the first memory cell, the back gate of the third memory cell is overlapped with the body region of the third memory cell, the first dielectric layer is disposed between the body region of the first memory cell and the back gate of the first memory cell, and the first dielectric layer is disposed between the body region of the third memory cell and the back gate of the third memory cell.

45. The memory array of claim 44, wherein the back gate of the first memory cell is electrically connected to the back gate of the third memory cell.

46. A method for making a semiconductor structure, comprising:
(a) receiving a first structure including a first substrate over a first dielectric layer;
(b) defining an active area in the first substrate;
(c) forming a dual gate structure over the active area, wherein the dual gate structure comprises a first gate, a second gate comprising a first horizontal section laterally distanced from the first gate, and a spacing material laterally between the first gate and the first horizontal section of the second gate; and
(d) forming a source region and a drain region in the active area.

47. The method of claim 46, wherein the first substrate is a single crystalline substrate made of silicon, germanium, gallium arsenide (GaAs), indium phosphide (InP), silicon carbon (SiC), or gallium nitride (GaN).

48. The method of claim 46, wherein the step (c) comprises:
(c1) forming the first gate over the first gate dielectric;
(c2) forming the spacing material on a sidewall of the first gate;
(c3) forming the second gate adjacent to the spacing material such that the first gate and the second gate are spaced apart by the spacing material.

49. The method of claim 48, wherein the step (c2) comprises forming at least one of a first gate spacer and a second gate dielectric on the sidewall of the first gate.

50. The method of claim 46, wherein a body region in the active area is doped with a first type of material before step (c).

51. The method of claim 50, wherein in the step (d), the source region and the drain region are formed by doping regions of the active area with a second type of material different from the first type of material.

52. The method of claim 46, wherein the step (d) comprises forming the source region and the drain region extending through the thickness of the first substrate.

53. The method of claim 46 further comprising (e) forming a source contact on the source region and a drain contact on the drain region.

54. The method of claim 46, wherein in the step (a) the first structure further includes a second substrate, and the first dielectric layer is disposed between the first substrate and the second substrate.

55. The method of claim 54, further comprising:
(f) removing the second substrate; and
(g) forming a back gate on the first substrate, wherein the first substrate is between the dual gate structure and the back gate.

56. The method of claim 46, wherein in the step (a) the first structure further comprises a charge storage layer between the first substrate and the first dielectric layer.

57. The method of claim 46, wherein in the step (a) the first structure further includes a conductive layer, and the first dielectric layer is disposed between the first substrate and the conductive layer.

58. The method of claim 57, wherein in the step (a) the first structure further includes a second dielectric layer, wherein the conductive layer is disposed between the first dielectric layer and the second dielectric layer.

59. (canceled)

60. (canceled)
